(19) United States
(12) Patent Application Publication
(10) Pub. No.: US 2024/0094644 A1
(43) Pub. Date: Mar. 21, 2024

(54) SUBSTRATE TREATMENT APPARATUS AND TREATMENT SOLUTION SUPPLY METHOD

(71) Applicant: Tokyo Electron Limited, Tokyo (JP)

(72) Inventors: Makoto OGATA, Koshi City (JP); Katsuya HASHIMOTO, Koshi City (JP); Katsunori ICHINO, Koshi City (JP); Masataka TANAKA, Koshi City (JP); Kazuya KUDO, Koshi City (JP)

(21) Appl. No.: 18/465,420

(22) Filed: Sep. 12, 2023

(30) Foreign Application Priority Data
Sep. 21, 2022 (JP) 2022-149993
Jun. 12, 2023 (JP) 2023-096492

(51) Int. Cl. G03F 7/00

(52) U.S. Cl. CPC G03F 7/70808; G03F 7/7085; G03F 7/70925

(57) ABSTRACT

A substrate treatment apparatus includes: a plurality of solution treatment modules stacked at multiple stages, each configured to perform a treatment using a treatment solution on a substrate; and a solution supply unit configured to supply the treatment solution to the plurality of solution treatment modules, wherein: the solution supply unit includes supply pipelines provided with a solution feeder corresponding to the solution treatment modules; and the solution feeder includes a pump configured to pressure-feed the treatment solution to the corresponding solution treatment module and a filter configured to filtrate the treatment solution, and is arranged adjacent to the corresponding solution treatment module in a horizontal direction.

### CROSS REFERENCE TO RELATED APPLICATIONS

This application is based upon and claims the benefit of priority of the prior Japanese Patent Application No. 2022-149993, filed in Japan on Sep. 21, 2022 and the prior Japanese Patent Application No. 2023-96492, filed in Japan on Jun. 12, 2023, the entire contents of which are incorporated herein by reference.

### TECHNICAL FIELD

This disclosure relates to a substrate treatment apparatus and a treatment solution supply method

### BACKGROUND

Japanese Laid-open Patent Publication No. 2007-5576 discloses a resist coating and developing apparatus in which coat process stations each performing a resist coating treatment on a wafer are stacked at multiple stages. Further, the resist coating and developing apparatus disclosed in Patent Document 1 includes a chemical unit and a plurality of dispense units constituted by distribution from the chemical unit. The chemical unit is composed of a bottle which stores a resist, a liquid end which temporarily stores the resist, a filter which performs filtering of the resist, and so on. The dispense unit is composed of a low-pressure pump which feeds the resist, a dispense valve which performs supply control of the resist to be discharged from a nozzle of the coat process station, and soon. In Japanese Laid-open Patent Publication No. 2007-5576, each of the dispense units is arranged at a position close to the corresponding coat process station. Further, the nozzle of the coat process station is installed at a position higher by one stage than the corresponding dispense unit.

### SUMMARY

An aspect of this disclosure is a substrate treatment apparatus including: a plurality of solution treatment modules stacked at multiple stages, each configured to perform a treatment using a treatment solution on a substrate; and a solution supply unit configured to supply the treatment solution to the plurality of solution treatment modules, wherein: the solution supply unit includes supply pipelines provided with a solution feeder corresponding to the solution treatment modules; and the solution feeder includes a pump configured to pressure-feed the treatment solution to the corresponding solution treatment module and a filter configured to filtrate the treatment solution, and is arranged adjacent to the corresponding solution treatment module in a horizontal direction.

### BRIEF DESCRIPTION OF THE DRAWINGS

FIG. 1 is a plan view illustrating the outline of a configuration of a coating and developing apparatus as a substrate treatment apparatus according to an embodiment.

FIG. 2 is a view illustrating the outline of a configuration of a middle portion in a depth direction of the coating and developing apparatus.

FIG. 3 is a view illustrating the outline of a configuration of a first stack treatment block.

FIG. 4 is an explanatory view illustrating the outline of an example of a configuration of a solution supply unit.

FIG. 5 is a cross-sectional view of a discharge control valve.

FIG. 6 is a view for explaining a position of a solution feeder.

FIG. 7 is a diagram illustrating a state of the solution supply unit during a circulation operation.

FIG. 8 is a diagram illustrating a state of the solution supply unit during a discharge operation.

FIG. 9 is a diagram illustrating a state of the solution supply unit during a replenishment operation to a dispense pump.

FIG. 10 is a view illustrating an example of a state of a dispense pump during the replenishment operation to the dispense pump.

FIG. 11 is a diagram illustrating a state of the solution supply unit during a replenishment operation to an assist pump.

FIG. 12 is an explanatory view illustrating the outline of another example of the configuration of the solution supply unit.

FIG. 13 is a view for explaining a position of a solution feeder in the case of using the solution supply unit in FIG. 12.

FIG. 14 is an explanatory view illustrating the outline of still another example of the configuration of the solution supply unit.

FIG. 15 is a view for explaining a position of a solution feeder in the case of using the solution supply unit in FIG. 14.

FIG. 16 is a view illustrating another example of the position of the solution feeder.

FIG. 17 is a view illustrating still another example of the position of the solution feeder.

### DETAILED DESCRIPTION

In a photolithography step in a manufacturing process of a semiconductor device or the like, a series of treatments is performed to form a predetermined resist pattern on a substrate such as a semiconductor wafer (hereinafter, referred to as a “wafer”). The series of treatments includes, for example, a resist coating treatment of supplying a resist solution onto the substrate to form a resist film, an exposure treatment of exposing the resist film, a developing treatment of supplying a developing solution to the exposed resist film to develop it, and so on. Further, the series of treatments is performed in a coating and developing treatment apparatus being a substrate treatment apparatus in which various treatment modules for treating the substrate, a transfer mechanism for transferring the substrate, and so on are installed and which is connected to an exposure apparatus. Examples of the treatment modules installed in the coating and developing treatment apparatus include a solution treatment module which performs a treatment using a treatment solution such as a resist solution, namely, a solution treatment. Further, a plurality of solution treatment modules of the same kind (for example, resist coating apparatuses each for applying the resist solution to the substrate to form a resist film) are stacked at multiple stages in some cases in the coating and developing apparatus.

Further, in the coating and developing treatment apparatus, a solution supply unit is provided which supplies the treatment solution to the solution treatment module. The solution supply unit is provided with a filter which filtrates the treatment solution, namely, removes foreign substances from the treatment solution.

However, if the filter is provided, in the case where the plurality of solution treatment modules of the same kind are stacked at multiple stages as above, foreign substances are contained in the treatment solution to be discharged to the substrate depending on the solution treatment module and detected as defects on the substrate after the solution treatment or before the solution treatment in some cases.

Hence, the technique according to this disclosure suppresses occurrence of defects for each of solution treatment modules in a substrate treatment apparatus in which a plurality of solution treatment modules are stacked at multiple stages. Specifically, the technique according to this disclosure improves the defect performance of each of the solution treatment modules to make the defect performance almost equal among the solution treatment modules located at different layers in the substrate treatment apparatus in which the plurality of solution treatment modules are stacked at multiple stages.

Hereinafter, a substrate treatment apparatus and a treatment solution supply method according to embodiments will be explained with reference to the drawings. Note that, in the description, the same reference signs are given to components having substantially the same functional configurations to omit duplicate explanations.

<Coating and Developing Apparatus>

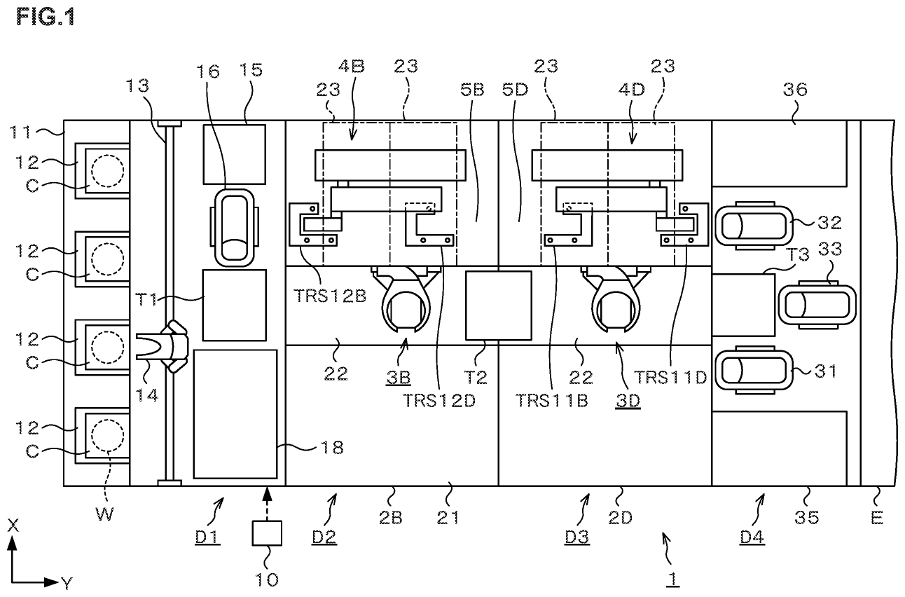

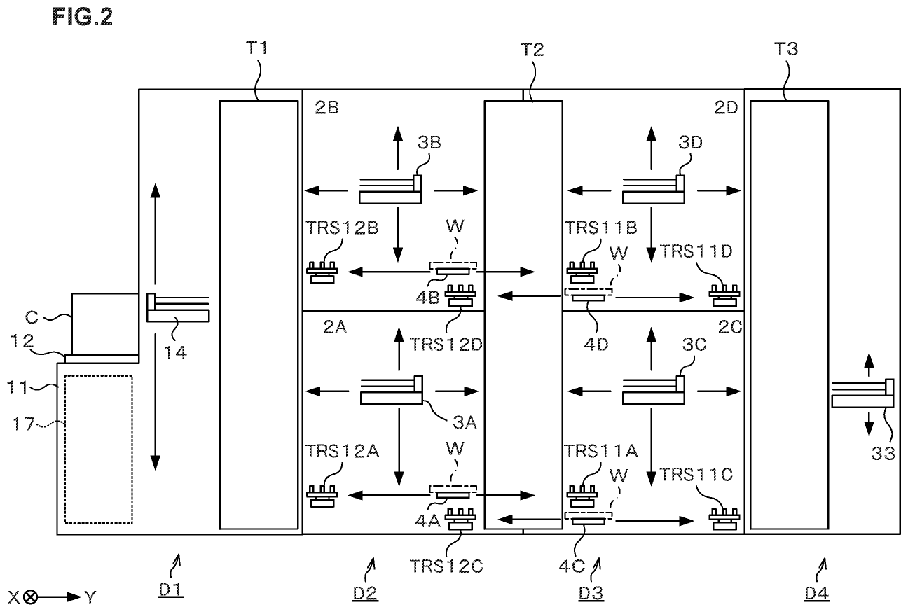

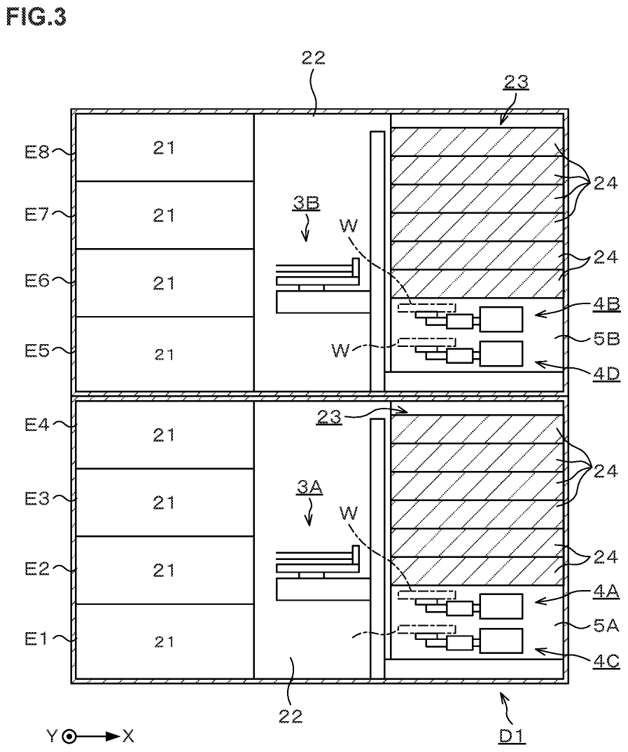

FIG. 1 is a plan view illustrating the outline of a configuration of a coating and developing apparatus 1 as a substrate treatment apparatus according to an embodiment. FIG. 2 is a view illustrating the outline of a configuration of a middle portion in a depth direction (X-direction) of the coating and developing apparatus 1. FIG. 3 is a view illustrating the outline of a configuration of a later-explained first stack treatment block.

As illustrated in FIG. 1 and FIG. 2, in the coating and developing apparatus 1, a carrier block D1, a first stack treatment block D2, a second stack treatment block D3, and an interface block D4 are arranged side by side in this order in a width direction (Y-direction in FIG. 1 and so on). Adjacent blocks among the carrier block D1, the first stack treatment block D2, the second stack treatment block D3, and the interface block D4 are connected to each other. Further, the carrier block D1, the first stack treatment block D2, the second stack treatment block D3, and the interface block D4 have respective housings which are partitioned from each other and in each of which a transfer region of the wafer W as a substrate is formed.

An exposure apparatus E is connected to the side (Y-direction positive side) of the interface block D4 opposite to the second stack treatment block D3.

To the coating and developing apparatus 1, for example, the wafer W is transferred in a state of being stored in a carrier C that is called a FOUP (Front Opening Unify Pod). Each of the first stack treatment block D2 and the second stack treatment block D3 is partitioned so as to be divided into two portions in the vertical direction. Each of the partitioned portions forms a treatment block having a treatment module and a main transfer mechanism which transfers the wafer W to the treatment module. In the following, the lower side and the upper side of the first stack treatment block D2 partitioned into the two portions in the vertical direction are called a treatment block 2A and a treatment block 2B respectively, and the lower side and the upper side of the second stack treatment block D3 similarly partitioned into two portions are called a treatment block 2C and a treatment block 2D respectively.

The treatment blocks 2A, 2C are adjacent to each other in the width direction (Y-direction) being the horizontal direction, and the treatment blocks 2A, 2C are collectively called lower treatment blocks in some cases. Further, the treatment blocks 2B, 2D are adjacent to each other in the width direction (Y-direction) being the horizontal direction, and the treatment blocks 2B, 2D are collectively called upper treatment blocks in some cases. FIG. 1 illustrates the upper treatment block. In each of the treatment blocks 2B, 2D being the upper treatment blocks, a shuttle (bypass transfer mechanism) is provided. The shuttle transfers the wafer W toward the block on the downstream side of a transfer route in a manner not to pass through any treatment module.

Note that the “module” is a place where the wafer W is mounted other than the transfer mechanism (including the shuttle). The module which performs a treatment on the wafer W is described as the treatment module as above, and the treatment also includes acquisition of an image for inspection.

In the carrier block D1, a carrier stage 11 is provided, for example, at an end portion on the opposite side (Y-direction positive side in FIG. 1 and FIG. 2) to the first stack treatment block D2. On the carrier stage 11, a plurality of stage plates 12 on which carriers C are mounted when the carriers C are transferred into/out of the coating and developing apparatus 1 are provided side by side in the depth direction (X-direction in FIG. 1 and so on).

Further, in the carrier block D1, a delivery tower T1 is provided at a middle portion in the depth direction (X-direction) at an end portion on the first stack treatment block D2 side (Y-direction negative side in FIG. 1 and so on). The delivery tower T1 is configured by stacking modules such as a delivery module on which the wafer W is temporarily mounted, at multiple stages in the vertical direction.

Further, in the carrier block D1, a transfer mechanism 14 movable on a transfer path 13 extending in the depth direction (X-direction) is provided at a middle portion in the width direction (Y-direction) being the horizontal direction. The transfer mechanism 14 is movable also in the vertical direction and around a vertical axis (θ-direction) and can transfer the wafer W between the carrier C on the stage plate 12 and the module in the delivery tower T1.

Further, in the carrier block D1, a hydrophobic treatment module 15 which performs a hydrophobic treatment on the wafer W is provided on the deep side (X-direction positive side in FIG. 1 and so on) of the delivery tower T1 and on the deep side end in the carrier block D1. The hydrophobic treatment modules 15 may be stacked at multiple stages in the vertical direction.

Further, in the carrier block D1, a transfer mechanism 16 is provided between the delivery tower T1 and the hydrophobic treatment module 15. The transfer mechanism 16 is movable in the vertical direction and around the vertical axis (θ-direction) and can transfer the wafer W between the module in the delivery tower T1 and the hydrophobic treatment module 15, between the modules in the delivery tower T1, and so on. Further, the transfer mechanism 16 can transfer the wafer W also to a delivery module TRS12B for a shuttle 4B provided in the treatment block 2B.

Further, a region below the stage plate 12 in the carrier block D1 is a storage source region 17 in which a storage bottle for storing a treatment solution is housed. In the storage bottle housed in the storage source region, a treatment solution to be used in the first stack treatment block D2 is stored.

Note that in a region on the front side (X-direction negative side in FIG. 1 and so on) of the delivery tower T1 in the carrier block D1 is a storage region 18 in which a later-explained solution feeder is housed. A concrete configuration of the storage region 18 will be explained later.

In the first stack treatment block D2, as illustrated in FIG. 3, resist film forming modules 21 as solution treatment modules are stacked at multiple stages (for example, four or more stages, and eight stages in the example of the drawing) at a portion on the front side (X-direction negative side). Specifically, the portion on the front side of the first stack treatment block D2 is divided along the vertical direction and partitioned into a plurality of (for example, four or more, and eight in the example of FIG. 3) tiers, and the resist film forming module 21 is provided at each of the tiers. In the following, the eight tiers are called tiers E1 to E8 in order from the lower side. The tiers E1 to E4 on the lower side are included in the treatment block 2A, and the tiers E5 to E8 on the upper side are included in the treatment block 2B.

As illustrated in FIG. 1 and FIG. 3, a transfer region 22 of the wafer W is provided on the deep side (X-direction positive side) of the tiers E5 to E8 in the treatment block 2B. The transfer region 22 is formed in a linear shape in plan view from one end to the other end of the treatment block 2B in the width direction (Y-direction) and formed from the tier E5 to the tier E8 in the vertical direction. On the deep side (X-direction positive side) of the transfer region 22, a treatment module stack 23 is provided in which the treatment modules are stacked at multiple stages (seven stages in the example of the drawing). For example, two treatment module stacks 23 are provided at an interval, for example, in the width direction (Y-direction). Each of the treatment module stacks 23 includes, for example, a heating module 24 which performs a heat treatment for removing a solvent in a resist film on the wafer W.

In the transfer region 22, a main transfer mechanism 3B is provided. The main transfer mechanism 3B is movable in the width direction (Y-direction) and the vertical direction, and around the vertical axis (θ-direction) and can transfer the wafer W to each of the treatment modules in the treatment block 2B. The main transfer mechanism 3B can transfer the wafer W to a module located at the same height as the treatment block 2B, among the modules in the delivery tower T1 adjacent to the treatment block 2B in the width direction (Y-direction) and a later-explained delivery tower T2. Further, the main transfer mechanism 3B can transfer the wafer W also to a delivery module TRS for the shuttle 4B provided in the treatment block 2B.

Further, on the lower side of the treatment module stack 23 in the treatment block 2B, a partitioned flat space 5B is provided. The space 5B is formed from one end to the other end in the width direction (Y-direction) of the treatment block 2B. In the space 5B, the shuttle 4B and delivery modules TRS12B, TRS12D are provided.

Note that the treatment blocks 2A, 2C, 2D have configurations similar to that of the treatment block 2B except for the later-explained different points. Each of the treatment blocks 2A, 2C, 2D includes a main transfer mechanism corresponding to the main transfer mechanism 3B and, as a reference sign of the main transfer mechanism, the same alphabet as that attached to the treatment block having the main transfer mechanism is used in place of “B” in the following explanation and the drawings. Specifically, “3A” is used for the main transfer mechanism in the treatment block “2A”. The other main transfer mechanism corresponding to the main transfer mechanism 3B can transfer the wafer W to the treatment module and the delivery module TRS for the shuttle in the treatment block in which the main transfer mechanism is provided and to the delivery tower adjacent to the treatment block in the width direction (Y-direction).

Further, for a reference sign of the space where the shuttle can be installed corresponding to the above space 5B, the same alphabet as the alphabet attached to the treatment block is used in place of “B”. Further, in the case where the shuttle is provided in the treatment block, the same alphabet as the alphabet attached to the treatment block is used as a reference sign of the shuttle. Further, for the delivery module TRS for the shuttle, the same alphabet as that of the treatment block in which the shuttle is provided is used. Further, regarding the delivery modules TRS for the shuttles, among those used for the same shuttle, 11 is attached to that on the interface block D4 side and 12 is attached to that on the carrier block D1 side, in front of the alphabet attached to the treatment block. Giving a specific example for the above rule of the reference sign, 4D is used for the shuttle provided in the treatment block 2D, and TRS11D, TRS12D are used respectively for the delivery modules on the interface block D4 side and the carrier block D1 side respectively for the shuttle 4D.

The different point of the treatment block 2A from the treatment block 2B is that the transfer region 22 is formed from the tier E1 to the tier E4 in the vertical direction in the treatment block 2A.

The second stack treatment block D3 has almost the same configuration as that of the first stack treatment block D2. The second stack treatment block D3 will be explained mainly for the different points from the first stack treatment block D2 in the following.

The treatment block 2D is the same as the treatment block 2B regarding the positional relation among the transfer region 22, the treatment module stack 23, the main transfer mechanism, and the space for installing the shuttle stacked on the treatment module. However, in each of the tiers E5 to E8 in the treatment block 2D, a developing module is provided which develops the wafer W with a developing solution. Further, also in the treatment module stack 23 in the treatment block 2D, heating modules are provided, and the heating modules are provided for PEB. Further, for the treatment module stack 23 in the treatment block 2D, an inspection module is provided which images the wafer W for determining the presence or absence of an abnormality of the wafer W (namely, acquiring an image of the wafer W for inspection). The space 5D for the shuttle in the treatment block 2D is located at the same height as the space 5B and is communicated with the space 5B. In the space 5D, the shuttle 4D, and the delivery modules TRS 11B, 11D for the shuttle are provided.

The different point of the treatment block 2C from the treatment block 2D is that the transfer region 22 is formed from the tier E1 to the tier E4 in the vertical direction in the treatment block 2C.

The delivery tower T2 is provided at an end portion on the first stack treatment block D2 side (Y-direction negative side in FIG. 1 and so on) in the transfer region 22 in the second stack treatment block D3. The delivery tower T2 is located in a manner that its part overlaps with an end portion on the second stack treatment block D3 side (Y-direction positive side in FIG. 1 and so on) in the transfer region 22 in the first stack treatment block D2 in plan view. The delivery tower T2 is configured by stacking modules such as a delivery module at multiple stages in the vertical direction.

The interface block D4 includes a delivery tower T3 at the middle portion in the depth direction (X-direction in FIG. 1). The delivery tower T3 is configured by stacking modules such as the delivery module at multiple stages in the vertical direction. On the front side (X-direction negative side), the deep side (X-direction positive side), and the exposure apparatus E side (Y-direction positive side in FIG. 1 and so on) of the delivery tower T3, transfer mechanisms 31, 32, 33 are provided, respectively. The transfer mechanisms 31, 32, 33 are movable in the vertical direction and around the vertical axis (θ-direction).

On the front side (X-direction positive side) of the transfer mechanism 31, a rear surface cleaning module 35 is provided which supplies a cleaning solution to the rear surface of the wafer W and cleans it. The rear surface cleaning modules 35 may be stacked at multiple stages in the vertical direction. On the deep side (X-direction positive side) of the transfer mechanism 32, a post-exposure cleaning module 36 is provided which supplies a cleaning solution to the front surface of the wafer W after exposure. The post-exposure cleaning modules 36 may be stacked at multiple stages in the vertical direction. Each of the transfer mechanisms 31 to 33 can transfer the wafer W to the module in the delivery tower T3. Further, the transfer mechanism 31 can transfer the wafer W to the rear surface cleaning module 35, the transfer mechanism 32 can transfer the wafer W to the post-exposure cleaning module 36, and the transfer mechanism 33 can transfer the wafer W to the exposure apparatus E.

Here, the shuttles 4B, 4D and the delivery module TRS for each shuttle will be explained.

The shuttle 4B transfers the wafer W from the treatment block 2D toward the carrier block D1. As illustrated in FIG. 1, the delivery module TRS 12B of the delivery modules TRS 11B, 12B for the shuttle 4B is provided at the end portion on the carrier block D1 side (Y-direction negative side) in the space 5B so as to be able to deliver the wafer W to/from the transfer mechanism 14 in the carrier block D1. The delivery module TRS 11B is provided at the end portion on the treatment block 2B side (Y-direction negative side) in the space 5D and closer to the interface block D4 side (Y-direction positive side) than the delivery tower T2 so as to be able to deliver the wafer W to/from the main transfer mechanism 3D in the treatment block 2D.

The shuttle 4D transfers the wafer W from the treatment block 2B toward the interface block D4. The delivery module TRS 11D of the delivery modules TRS 11D, 12D for the shuttle 4D is provided at the end portion on the interface block D4 side (Y-direction positive side) in the space 5D so as to be able to deliver the wafer W to/from the transfer mechanism 32 in the interface block D4. The delivery module TRS 12D is provided at the end portion on the treatment block 2D side (Y-direction positive side) in the space 5B and closer to the carrier block D1 side (Y-direction negative side) than the delivery tower T2 so as to be able to deliver the wafer W to/from the main transfer mechanism 3B in the treatment block 2B.

Note that the shuttle 4A transfers the wafer W from the treatment block 2C toward the carrier block D1. The arrangement positions of the delivery modules TRS 11A, 12A for the shuttle 4A are the same as those of the delivery modules TRS 11B, 12B for the shuttle 4B.

Further, the shuttle 4C transfers the wafer W from the treatment block 2A toward the interface block D4. The arrangement positions of the delivery modules TRS 11C, 12C for the shuttle 4C are the same as those of the delivery modules TRS 11D, 12D for the shuttle 4D.

Further, in the coating and developing apparatus 1, a controller 10 is provided. The controller 10 is a computer including, for example, a processor such as a CPU and a memory, and has a program storage (not illustrated) which stores a program including a command to be executed by the processor. The program storage stores the program including a command for controlling operations of a drive system of the above various treatment modules and various transfer mechanisms to perform a later-explained wafer treatment. The program storage further stores a program including a command for performing treatments by the later-explained solution supply unit. Note that the above programs may be the ones recorded in a computer-readable storage medium and installed from the storage medium into the controller. The storage medium may be a transitory storage medium or a non-transitory storage medium.

<Wafer Treatment>

Next, examples of the wafer treatment using the coating and developing apparatus 1 and the transfer route will be explained.

For example, the wafer W is first taken by the transfer mechanism 14 out of the carrier C transferred into the carrier block D1 of the coating and developing apparatus 1 and mounted on the stage plate 12, and transferred to the delivery module in the delivery tower T1.

Subsequently, the wafer W is transferred by the transfer mechanism 16 to the hydrophobic treatment module 15 and subjected to a hydrophobic treatment. The wafer W is then returned by the transfer mechanism 16 to the delivery tower T1.

Next, the wafer W is transferred by the main transfer mechanism 3A or the main transfer mechanism 3B to the resist film forming module 21 and the heating module 24 in this order in the first stack treatment block D2, and a resist film is formed thereon. The wafer W after the formation of the resist film is transferred by the main transfer mechanism 3A or the main transfer mechanism 3B to the delivery module in the delivery tower T2, and transferred by the main transfer mechanism 3C or the main transfer mechanism 3D to the delivery module in the delivery tower T3 in the interface block D4. Note that the wafer W after the formation of the resist film may be transferred from the treatment block 2A to the delivery tower T3 while bypassing the second stack treatment block D3, via the main transfer mechanism 3A, the shuttle 4C, the delivery modules TRS 12C, 11C, and the transfer mechanism 32. Besides, the wafer W after the formation of the resist film may be transferred from the treatment block 2B to the delivery tower T3 while bypassing the second stack treatment block D3, via the main transfer mechanism 3B, the shuttle 4D, the delivery modules TRS 12D, 11D, and the transfer mechanism 32.

Subsequently, the wafer W is transferred by the transfer mechanism 31 to the rear surface cleaning module 35, and the rear surface is cleaned. The wafer W is then returned by the transfer mechanism 31 to the delivery tower T3, and then transferred by the transfer mechanism 33 to the exposure apparatus E and subjected to an exposure treatment. The wafer W after the exposure is returned by the transfer mechanism 33 to the delivery tower T3, then transferred by the transfer mechanism 32 to the post-exposure cleaning module 36, and cleaned.

The wafer W after the cleaning by the post-exposure cleaning module 36 is, for example, first returned by the transfer mechanism 32 to the delivery tower T3. The wafer W is then transferred by the main transfer mechanism 3C or the main transfer mechanism 3D to the heating module, the developing module, and the inspection module in this order in the second stack treatment block D3, a resist pattern is formed after the PEB treatment, and then the presence or absence of an abnormality is determined. Next, the wafer W is returned by the main transfer mechanism 3C or the main transfer mechanism 3D to the delivery tower T2, and then returned by the main transfer mechanism 3A or the main transfer mechanism 3B to the delivery tower T1. Note that the wafer W subjected to the treatment by the inspection module may be returned from the treatment block 2C to the delivery tower T1 while bypassing the first stack treatment block D2, via the main transfer mechanism 3C, the shuttle 4A, the delivery modules TRS 11A, 12A, and the transfer mechanism 16. Further, the wafer W subjected to the treatment by the inspection module may be returned from the treatment block 2D to the delivery tower T1 while bypassing the first stack treatment block D2, via the main transfer mechanism 3D, the shuttle 4B, the delivery modules TRS 11B, 12B, and the transfer mechanism 16.

The wafer W is then returned by the transfer mechanism 14 from the delivery tower T1 to the carrier C.

<Solution Supply Unit>

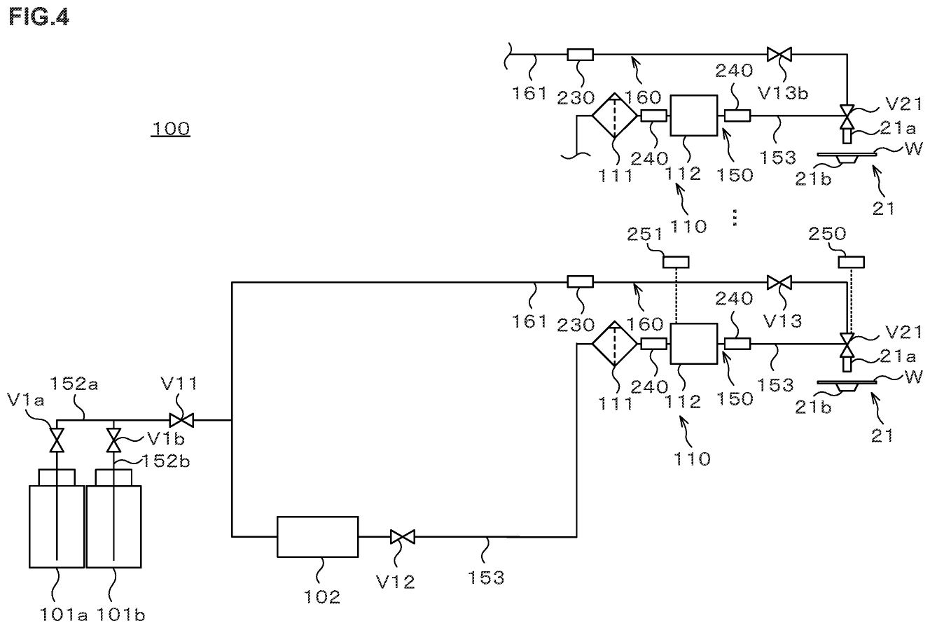

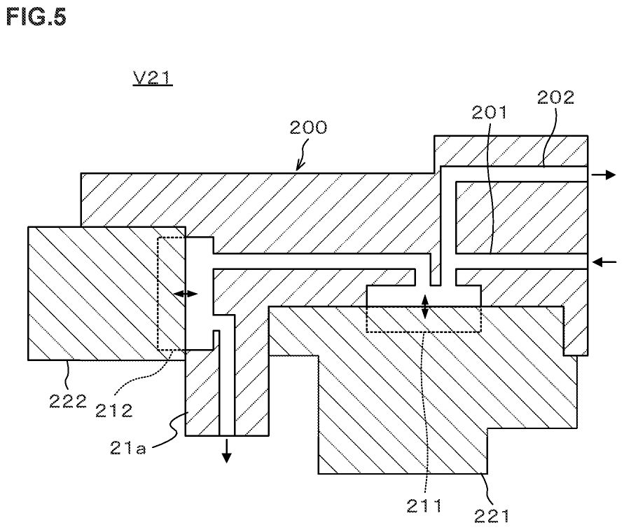

Next, a configuration of a solution supply unit 100 included in the coating and developing apparatus 1 will be explained. FIG. 4 is an explanatory view illustrating the outline of an example of the configuration of the solution supply unit 100. FIG. 5 is a cross-sectional view of a later-explained discharge control valve V21.

The solution supply unit 100 supplies a resist solution as a treatment solution to each of the plurality of the resist film forming modules 21. In this embodiment, the solution supply unit 100 supplies the resist solution to each of the resist film forming modules 21 provided at the tiers E1 to E8. Specifically, the solution supply unit 100 supplies the resist solution to a discharge nozzle 21a as a discharger of each of the plurality of resist film forming modules 21 as illustrated in FIG. 4. The discharge nozzle 21a discharges the resist solution. Specifically, the discharge nozzle 21a discharges the resist solution to the wafer W held on a spin chuck 21b being a holder.

Note that in the case of collectively explaining members relating to the solution supply unit 100 which have a common function, such as later-explained resist solution bottles 101a, 101b, the alphabets of reference signs are omitted as appropriate in the following. For example, in the case of collectively explaining the resist solution bottles 101a, 101b, they are abbreviated as appropriate to “resist solution bottles 101”.

The solution supply unit 100 has a supply pipeline 150 provided with a later-explained solution feeder, in a manner to correspond to the resist film forming module 21 at the supply destination of the resist solution. In this example, the solution supply unit 100 has the supply pipeline 150 provided with the later-explained solution feeder for each of the resist film forming modules 21. A downstream-side end of the supply pipeline 150 is connected to a corresponding resist film forming module 21. Specifically, the downstream-side end of the supply pipeline 150 is connected to the discharge nozzle 21a of a corresponding resist film forming module 21. An upstream-side end of the supply pipeline 150 is connected to a plurality of (two in the example of the drawing) resist solution bottles 101a, 101b. Specifically, the plurality of supply pipelines 150 join together on the upstream side to form a main supply pipeline, an upstream side from the main supply pipeline is branched from the main supply pipeline to branch supply pipelines 152a, 152b, and respective upstream-side ends of the branch supply pipelines 152a, 152b are connected to the resist solution bottles 101a, 101b. The branch supply pipeline 152a and the branch supply pipeline 152b have opening/closing valves V1a, Vlb as switching valves each for switching between execution and stop of replenishment of the resist solution from a corresponding resist solution bottle 101.

The resist solution bottle 101 is a storage source which stores the resist solution and is replaceable. In this embodiment, the plurality of resist solution bottles 101 are connected as explained above, so that even while one resist solution bottle 101 is being replaced, the replenishment of the resist solution from the other resist solution bottle 101 is possible.

In this embodiment, the supply pipeline 150 is not provided with a temporary storage such as a buffer tank for temporarily storing the resist solution which has been stored in the resist solution bottle 101. Accordingly, it is possible to prevent foreign substances generated on an inner wall surface (specifically, its gas-liquid interface) of the temporary storage from mixing into the resist solution to be supplied from the supply pipeline 150 to the discharge nozzle 21a. Further, because the supply pipeline 150 is not provided with the temporary storage, it is possible to shorten the time during which the resist solution stays in the solution supply unit 100 from when the replenishment of the resist solution from the resist solution bottle 101 to the supply pipeline 150 to when the resist solution is discharged via the discharge nozzle 21a. Accordingly, it is possible to prevent foreign substances from mixing into the treatment solution to be discharged via the discharge nozzle 21a.

Each of the supply pipelines 150 is provided with the solution feeder 110. The solution feeder 110 has a filter 111 which filtrates the resist solution, and a dispense pump 112 as a first pump which pressure-feeds the resist solution to a corresponding resist film forming module 21. The filter 111 and the dispense pump 112 are provided in this order, for example, from the upstream side. In other words, the dispense pump 112 pressure-feeds the resist solution filtrated by the filter 111.

On the upstream side of the solution feeder 110 on the supply pipeline 150, an assist pump 102 as a second pump is provided which pressure-feeds the resist solution to the solution feeder 110. The assist pump 102 is provided, for example, for each supply pipeline 150.

The dispense pump 112 and the assist pump 102 are each composed of, for example, a diaphragm pump being a variable displacement pump. Specifically, the dispense pump 112 and the assist pump 102 are each partitioned by a diaphragm being a flexible member into a pump chamber (also called a storage chamber) and an operating chamber. The pump chamber is filled with the resist solution.

The dispense pump 112 and the assist pump 102 may be configured to be able to not only pressure-feed but also suck the resist solution.

On the upstream side of the assist pump 102 on the supply pipeline 150, a first opening/closing valve V11 is provided. The first opening/closing valve V11 is provided, for example, for each supply pipeline 150.

Note that the assist pump 102 and the first opening/closing valve V11 may be provided in common among the plurality of supply pipelines 150. In this case, the assist pump 102 and the first opening/closing valve V11 are interposed in the main supply pipeline.

Between the assist pump 102 and the solution feeder 110 on the supply pipeline 150, a second opening/closing valve V12 is provided. The second opening/closing valve V12 is provided, for example, for each supply pipeline 150.

Further, the supply pipeline 150 is provided with a discharge control valve V21 on the downstream side of the solution feeder 110. The discharge control valve V21 is provided, for example, for each discharge nozzle 21a, namely, for each supply pipeline 150 in this example.

The discharge control valve V21 has a main body part 200 as illustrated in FIG. 5. Inside the main body part 200, an in-valve supply flow path 201 and an in-valve return flow path 202 are formed. In the discharge control valve V21, the in-valve return flow path 202 is located above the in-valve supply flow path 201. In the discharge control valve V21, for example, the main body part 200 is integrated with the discharge nozzle 21a. The discharge nozzle 21a may be detachably attached to the main body part 200.

A downstream-side end of the in-valve supply flow path 201 is connected to and communicated with the discharge nozzle 21a. To an upstream-side end of the in-valve supply flow path 201, a downstream-side end of a supply pipe 153 which constitutes the supply pipeline 150 together with the in-valve supply flow path 201 is connected.

Further, in the in-valve supply flow path 201, a first valve element 211 and a second valve element 212 are provided in order from the upstream side. Each of the first valve element 211 and the second valve element 212 performs at least one of the opening/closing of the in-valve supply flow path 201 and the adjustment of the opening degree of the in-valve supply flow path 201.

Further, the discharge control valve V21 has a first actuator 221 which drives the first valve element 211 and a second actuator 222 which drives the second valve element 212.

In the discharge control valve V21, the first valve element 211, the second valve element 212, the first actuator 221, and the second actuator 222 are provided not to be located on the upper side than the upper end of the main body part 200. For example, the first valve element 211, the second valve element 212, the first actuator 221, and the second actuator 222 are attached to a lower portion of the main body part 200.

The in-valve return flow path 202 will be explained later.

As illustrated in FIG. 4, the solution supply unit 100 has a return pipeline 160. The return pipeline 160 is provided for each supply pipeline 150, namely, for each resist film forming module 21 in this example.

One end of the return pipeline 160 is branched from the downstream side of the dispense pump 112 and the filter 111 on a corresponding supply pipeline 150. Specifically, the one end of the return pipeline 160 is branched from the supply pipeline 150 in the discharge control valve V21 of the corresponding supply pipeline 150. More specifically, the one end of the in-valve return flow path 202 of the discharge control valve V21 constituting the return pipeline 160 is branched from the upstream side of the second valve element 212 on the in-valve supply flow path 201 as illustrated in FIG. 5. The other end of the in-valve return flow path 202 is connected to one end of a return pipe 161 constituting the return pipeline 160 together with the in-valve return flow path 202.

As illustrated in FIG. 4, the other end of the return pipeline 160 is connected to the downstream side of the first opening/closing valve V11 and the upstream side of the dispense pump 112 and the filter 111 on the corresponding supply pipeline 150. Specifically, the other end of the return pipeline 160 and the other end of the return pipe 161 are connected between the first opening/closing valve V11 and the assist pump 102 on the corresponding supply pipeline 150.

Accordingly, the return pipeline 160 constitutes a circulation path of the treatment solution together with a portion where the dispense pump 112 and the filter 111 are interposed in the corresponding supply pipeline 150.

The solution supply unit 100 has a foreign substance detector 230 which detects foreign substances in the resist solution. The foreign substance detector 230 is provided, for example, for each resist film forming module 21. Further, the foreign substance detector 230 is interposed, for example, in the return pipeline 160. In other words, the foreign substance detector 230 detects foreign substances in the resist solution flowing through the return pipeline 160.

The foreign substance detector 230 has, for example, an irradiator (not illustrated) which irradiates the fluid flowing through the pipeline provided with the foreign substance detector 230 with light, and a light receiver (not illustrated) which receives light radiated from the irradiator and transmitted through the fluid flowing through the pipeline. The foreign substance detector 230 detects foreign substances in the fluid in the flow path based on the light reception result by the light receiver.

Further, between the one end and the foreign substance detector 230 on the return pipeline 160, a third opening/closing valve V13 is interposed.

Further, the solution supply unit 100 has a flowmeter 240. The flowmeter 240 is arranged in a manner to cover the outer peripheral surface of the supply pipe 153 on the outside of the supply pipe 153. Further, the flowmeter 240 is detachably fixed to the supply pipe 153, specifically, fixed to the supply pipe 153 by pinching the supply pipe 153. The flowmeter 240 measures the flow rate of the resist solution flowing through the inside of the supply pipe 153 (specifically, the inside of a portion to which the flowmeter 240 is attached on the supply pipe 153), without contact with the resist solution. Specifically, the flowmeter 240 is intended to measure the flow rate of the resist solution, but does not have a wetted surface to the resist solution or a joint to the supply pipe 153. For the measuring method of the flow rate by the flowmeter 240, a publicly-known method (for example, a method using ultrasonic wave) can be employed.

The flowmeter 240 is provided, for example, between the filter 111 and the dispense pump 112 on the supply pipeline 150 or on the downstream side of the dispense pump 112 on the supply pipeline 150.

Furthermore, the solution supply unit 100 further has a regulator 250 which controls the operation of the discharge control valve V21 and a regulator 251 which controls the operation of the dispense pump 112.

The regulator 250 is, for example, an electropneumatic regulator which controls the operation of the discharge control valve V21 by air pressure. The regulator (hereinafter, referred to as an “electropneumatic regulator”) 250 specifically adjusts the air pressure to be supplied to the first actuator 221 which drives the first valve element 211 to control the opening/closing of the in-valve supply flow path 201 by the first valve element 211 or the opening degree of the in-valve supply flow path 201 by the first valve element 211. Further, the electropneumatic regulator 250 specifically adjusts the air pressure to be supplied to the second actuator 222 which drives the second valve element 212 to control the opening/closing of the in-valve supply flow path 201 by the second valve element 212 or the opening degree of the in-valve supply flow path 201 by the second valve element 212.

The regulator 251 is, for example, an electropneumatic regulator which controls the operation of the dispense pump 112 by air pressure. The regulator (hereinafter, referred to as an “electropneumatic regulator”) 251 specifically controls the pressure in the operating chamber of the dispense pump 112 being the diaphragm pump by air pressure supplied into the operating chamber.

In the solution supply unit 100, the electropneumatic regulator 250 is not integrated with the discharge control valve V21 but is a separate body. In particular, a portion including a circuit board used for control of the air pressure for driving at least one of the first valve element 211 and the second valve element 212 in the electropneumatic regulator 250 is a separate body from the discharge control valve V21, and is not in close contact with the main body part 200 but is arranged at a position away from the discharge control valve V21.

Further, in the solution supply unit 100, the electropneumatic regulator 251 is not integrated with the dispense pump 112 but is a separate body. In particular, a portion including a circuit board used for control of the pressure in the operating chamber in the electropneumatic regulator 251 is a separate body from the dispense pump 112, and is not in close contact with the dispense pump 112 but is arranged at a position away from the dispense pump 112.

Note that for each of the valves provided in the solution supply unit 100, an electromagnetic valve or an air-operated valve controllable by the controller 10 is used, and each valve and the controller 10 are electrically connected. Further, the controller 10 is electrically connected to the dispense pump 112 and the assist pump 102. With this configuration, the series of treatments by the solution supply unit 100 can be automatically performed under the control of the controller 10.

Further, the measurement result by the foreign substance detector 230 and the measurement result by the flowmeter 240 are output to the controller 10.

<Position of the Solution Feeder 110>

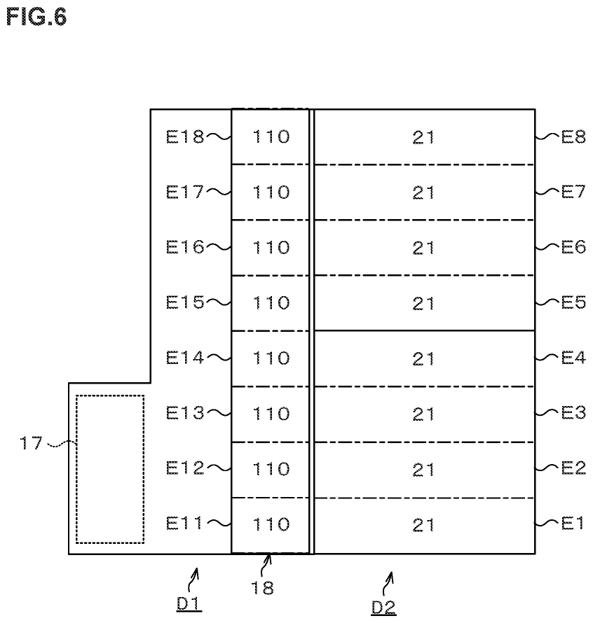

Subsequently, the position of the solution feeder 110 will be explained. FIG. 6 is a view for explaining the position of the solution feeder 110.

As explained above, the solution supply unit 100 has the supply pipeline 150 provided with the solution feeder 110 for each resist film forming module 21. Further, each solution feeder 110 has the dispense pump 112 and the filter 111 for a corresponding resist film forming module 21. Further, as explained above, a region on the front side (X-direction negative side in FIG. 1 and so on) of the delivery tower T1 in the carrier block D1, namely, a region in the carrier block D1 adjacent to the resist film forming module 21 in the width direction (Y-direction) is a housing region 18 in which the solution feeder 110 is housed.

The housing region 18 is divided along the vertical direction similarly to the portion on the front side (X-direction negative side) of the first stack treatment block D2 and partitioned into a plurality of (eight in the example of the drawing) tiers, and the solution feeder 110 is housed at each of the tiers. In the following, the eight tiers are called tiers E11 to E18 in order from the lower side.

The tier E11 is located at the same height as the tier E1 and houses the solution feeder 110 interposed in the supply pipeline 150 corresponding to the resist film forming module 21 provided at the tier E1.

Similarly, the tier E12 is located at the same height as the tier E2 and houses the solution feeder 110 interposed in the supply pipeline 150 corresponding to the resist film forming module 21 provided at the tier E2.

This also applies to the tiers E13 to E18.

In the above manner, each of the solution feeders 110 is arranged adjacent to the corresponding resist film forming module 21 in the width direction (Y-direction) being the horizontal direction, in the carrier block D1. Specifically, the solution feeder 110 is arranged at the tier in the carrier block D1 adjacent to the tier at which the corresponding resist film forming module 21 in the horizontal direction is provided. Note that “adjacent” includes that adjacent objects are in contact with each other and that adjacent objects are not in contact with each other but exist close to each other.

In the case where the foreign substance detector 230 is provided for each resist film forming module 21, the foreign substance detector 230 may also be arranged adjacent to the corresponding resist film forming module 21 in the width direction (Y-direction), in the carrier block D1. Specifically, for example, the foreign substance detector 230 corresponding to the resist film forming module 21 provided at the tier E1 may be house at the tier E11.

<Operation of the Solution Supply Unit 100>

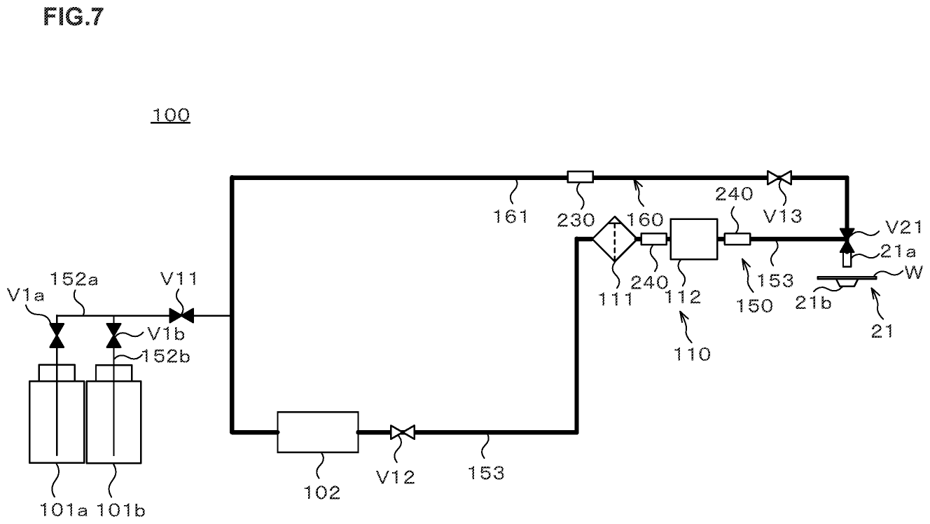

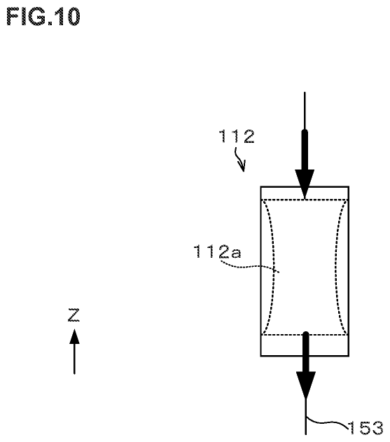

Next, the operation of the solution supply unit 100 will be explained based on FIG. 7 to FIG. 11. FIG. 7 to FIG. 9 and FIG. 11 are diagrams illustrating the states of the solution supply unit 100 during the circulation operation, during the discharge operation, during the replenishment operation to the assist pump 102, and during the replenishment operation to the dispense pump 112, respectively. FIG. 10 is a view illustrating an example of the state of the dispense pump 112 during the replenishment operation to the dispense pump 112. In FIG. 7 to FIG. 9 and FIG. 11, the valves in an open state are indicated in white, the valves in a close state are indicated in black, and the pipes through which the resist solution flows are indicated by thick lines, and thereby explanation of the open/closed states of the other valves is omitted as appropriate. Note that before each of the circulation operation and the discharge operation, the supply pipeline 150 and the return pipeline 160 are assumed to be filled with the resist solution in advance. Further, each of the following operations is performed under the control of the controller 10. Further, during each of the operations, the driving of the discharge control valve V21 is controlled by the electropneumatic regulator 250 configured as a separate body from the discharge control valve V21, and the driving of the dispense pump 112 is controlled by the electropneumatic regulator 251 configured as a separate body from the dispense pump 112.

<Circulation>

In the solution supply unit 100, the resist solution is circulated in the circulation path including the return pipeline 160 so as to prevent the resist solution from staying in the supply pipeline 150 when the resist solution is not supplied to the discharge nozzle 21a, namely, when the resist solution is not discharged from the discharge nozzle 21a. Specifically, as illustrated in FIG. 7, the first opening/closing valve V11 and the discharge control valve V21 are brought into a closed state, and the second opening/closing valve V12 and the third opening/closing valve V13 are brought into an open state. Then, the dispense pump 112 and the assist pump 102 are driven.

Thus, the resist solution is pressure-fed from the dispense pump 112 and the assist pump 102, and the resist solution passed through the filter 111 and the dispense pump 112 in the supply pipeline 150 is returned to the upstream side of the filter 111 and the dispense pump 112 on the supply pipeline 150 and circulates. Specifically, the resist solution passed through the filter 111 and the dispense pump 112 in the supply pipeline 150 is returned from the inside of the discharge control valve V21 to the upstream side of the filter 111 and the dispense pump 112 on the supply pipeline 150, and thereby circulates while being filtrated by the filter 111.

The aforementioned circulation is performed also at the startup of the solution supply unit 100. In this case, the above circulation is performed such that the resist solution is filtrated by the filter 111 a plurality of times.

Performing the circulation of the resist solution as above can prevent particles adhering to the filter 111 and so on from mixing into the resist solution due to staying.

Further, during the circulation operation, the foreign substances in the resist solution flowing through the return pipeline 160, namely, the foreign substances in the resist solution to be returned to the upstream side of the filter 111 and the dispense pump 112 on the supply pipeline 150 are detected by the foreign substance detector 230.

Further, during the circulation operation, the detection by the foreign substance detector 230 is performed a plurality of times, specifically, the measurement of the number of foreign substances in the resist solution by the foreign substance detector 230 may be performed a plurality of times. The detection by the foreign substance detector 230 is, for example, periodically performed.

During the circulation operation, the flow velocity of the resist solution may be made lower than that during the discharge operation.

Further, during the circulation operation, at least one of the flow rate of the resist solution pressure-fed from the dispense pump 112 and the flow rate of the resist solution filtrated by the filter 111 and flowing toward the dispense pump 112 may be measured by the flowmeter 240.

<Discharge>

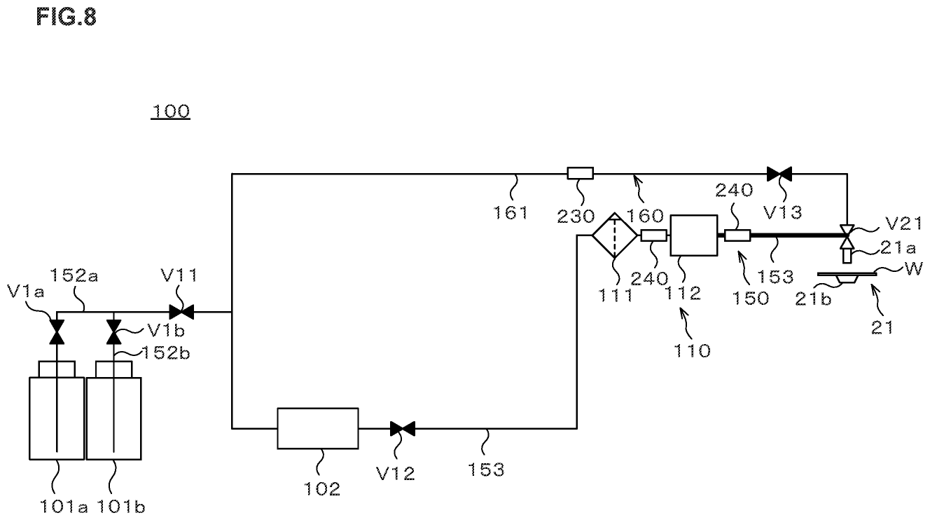

During the discharge from the discharge nozzle 21a, the resist solution is supplied to the resist film forming module 21 from the solution feeder 110 corresponding to the resist film forming module 21 having the discharge nozzle 21a and arranged adjacent to the resist film forming module 21 in the width direction (Y-direction). Specifically, as illustrated in FIG. 8, the second opening/closing valve V12 and the third opening/closing valve V13 corresponding to the resist film forming module 21 at the supply destination of the resist solution are brought into a closed state and the discharge control valve V21 is brought into an open state. In this state, the dispense pump 112 is driven.

Thus, the resist solution is pressure-fed from the dispense pump 112, and the resist solution filled in the supply pipeline 150 and passed through the filter 111 is supplied to the discharge nozzle 21a of the target resist film forming module 21.

Note that during the discharge operation, the flow rate of the resist solution pressure-fed from the dispense pump 112 may be measured by the flowmeter 240.

<Replenishment to the Dispense Pump 112>

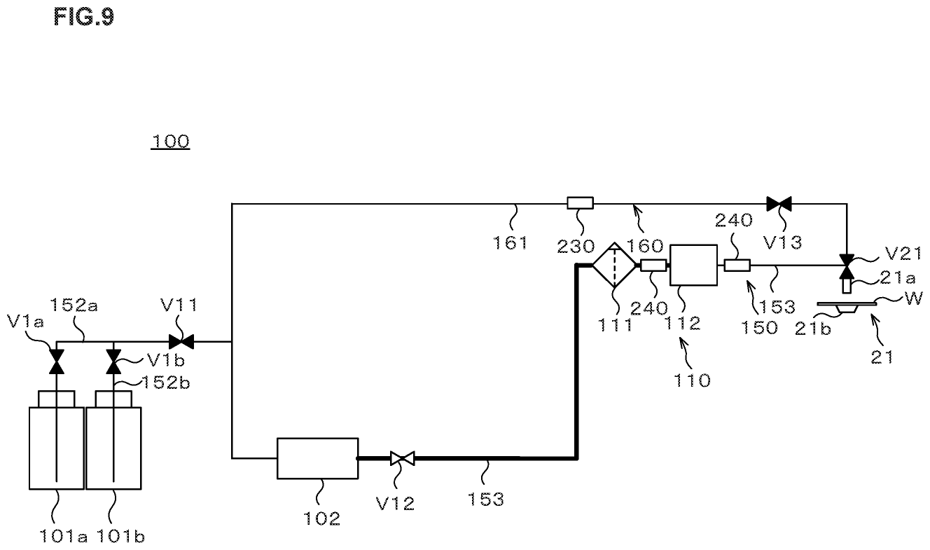

In the solution supply unit 100, after the discharge from the discharge nozzle 21a, the replenishment of the resist solution to the dispense pump 112 is performed. Specifically, as illustrated in FIG. 9, for example, the second opening/closing valve V12 is brought into an open state, and the first opening/closing valve V11, the discharge control valve V21, and the third opening/closing valve V13 are brought into a closed state. In this state, the assist pump 102 is driven without driving the dispense pump 112.

Thus, the resist solution is pressure-fed from the assist pump 102, and the dispense pump 112 is replenished with the resist solution filtrated by the filter 111.

Further, as illustrated in FIG. 10, in the case where the dispense pump 112 is a phragm pump having a storage chamber 112a, the dispense pump 112 may be arranged as follows. Specifically, the dispense pump 112 may be arranged such that the vertical upper side (Z-direction positive side in FIG. 6) of the storage chamber 112a is a primary side of the dispense pump 112 and the vertical lower side (Z-direction negative side in FIG. 6) of the storage chamber 112a is a secondary side of the dispense pump 112

In this case, the storage chamber 112a of the dispense pump 112 is replenished with the resist solution from a vertical upper side (Z-direction positive side) end of the storage chamber 112a. Further, in this case, the resist solution is pressure-fed from a vertical lower side (Z-direction negative side) end of the storage chamber 112a and supplied to the discharge nozzle 21a of the resist film forming module 21.

<Replenishment to the Assist Pump 102>

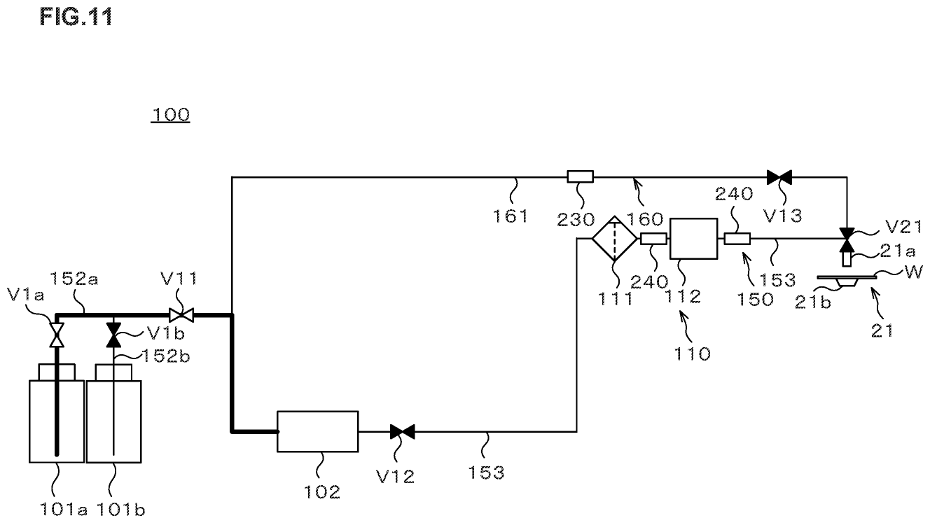

In the solution supply unit 100, after the replenishment to the dispense pump 112, the replenishment of the resist solution from the resist solution bottle 101 to the solution supply unit 100 is performed, specifically, the replenishment of the resist solution to the assist pump 102 is performed. More specifically, as illustrated in FIG. 11, for example, only one of the resist solution bottles 101a, 101b is selected as the replenishment source by the controller 10, and only the valve (opening/closing valve V1a in the example of the drawing) corresponding to the selected resist solution bottle 101 of the opening/closing valves V1a, V1b is brought into an open state. Further, the first opening/closing valve V11 is brought into an open sate, and the second opening/closing valve V12 and the third opening/closing valve V13 are brought into a closed state. In this state, the assist pump 102 is driven without driving the dispense pump 112.

Thus, the suction of the resist solution by the assist pump 102 is performed and the replenishment of the resist solution from the selected resist solution bottle 101 to the assist pump 102 is performed.

Once the replenishment to the dispense pump 112 and the replenishment to the assist pump 102 are finished, the above circulation operation is performed.

<Main Effects of this Embodiment>

As explained above, the coating and developing apparatus 1 according to this embodiment includes the plurality of resist film forming modules 21 stacked at multiple stages, and the solution supply unit 100 which supplies the resist solution to the plurality of resist film forming modules 21. The solution supply unit 100 has the supply pipeline 150 provided with the solution feeder 110, corresponding to the resist film forming module 21. Specifically, the solution supply unit 100 has the solution feeder 110 corresponding to the resist film forming module 21 for each resist film forming module 21. Further, each solution feeder 110 has the dispense pump 112 which pressure-feeds the resist solution to the corresponding resist film forming module 21, and the filter 111 which filtrates the resist solution. Each solution feeder 110 is arranged adjacent to the corresponding resist film forming module 21 in the width direction (Y-direction).

A conceivable form different from this embodiment (hereinafter, a comparative form) is a form in which the filter 111 is common among all of the resist film forming modules 21 included in the coating and developing apparatus 1. As compared with the comparative form, the solution feeder 110 having the filter 111 is provided as above in this embodiment, so that the distance from the filter 111 to the discharge nozzle 21a can be shortened for each of the plurality of resist film forming modules 21 included in the coating and developing apparatus 1. Therefore, it is possible to prevent the foreign substances from mixing into the resist solution at the portion from the filter 111 to the discharge nozzle 21a on the supply pipeline 150 for each of the resist film forming modules 21. Accordingly, it is possible to suppress the occurrence of defects when treating the wafer W using the supplied resist solution for each of the resist film forming modules 21.

Further, in this embodiment, the solution feeder 110 having the dispense pump 112 is provided as explained above, so that the level difference between the dispense pump 112 and the discharge nozzle 21a, namely, the head difference can be made almost equal among the resist film forming modules 21. In the case where the head difference is relatively large among the resist film forming modules 21 unlike the above, a long time is required to make the discharge performance from the discharge nozzle 21a a desired one for each of the resist film forming modules 21. In contrast, if the head difference is almost equal among the resist film forming modules 21, the discharge performance from the discharge nozzle 21a can be made a desired one for each of the resist film forming modules 21 in a relatively short time. In other words, according to this embodiment, it is possible to easily obtain a desired discharge performance for each of the resist film forming modules 21.

Further, in this embodiment, the electropneumatic regulator 250 is not integrated with the discharge control valve V21 but is a separate body as explained above. In particular, the portion including the circuit board used for control of the air pressure for driving the first valve element 211 in the electropneumatic regulator 250 is a separate body from the discharge control valve V21. This makes it possible to prevent the resist solution in the discharge control valve V21 from increasing in temperature under the influence of the temperature of the electropneumatic regulator 250 (specifically, the above circuit board) which gets high temperature during the execution of control. As a result, it is possible to prevent the occurrence of adverse effects due to the increase in temperature of the resist solution. Examples of the adverse effects occurred due to the increase in temperature of the resist solution include a change in resist solution discharge rate from the discharge nozzle 21a due to a change in density of the resist solution, a change in resist film thickness, and so on.

If the electropneumatic regulator is integrated with the discharge control valve, the resist film forming module 21 is large in height in the case where the discharge nozzle 21a is further integrated with the discharge control valve, and therefore there is room to improve the number of stacked resist film forming modules 21. Specifically, if the resist film forming modules 21 having relatively large height are stacked at eight or more stages, the height in the vertical direction of the whole apparatus becomes extremely large, thus causing a difficulty in apparatus transfer or causing a constraint in ceiling height of a factory in which the apparatus is installed. In contrast, in this embodiment, the discharge control valve V21, even if integrated with the discharge nozzle 21a, is a separate body from the electropneumatic regulator 250, so that the resist film forming module 21 can be made lower in height. As a result, it is possible to improve the point regarding the number of stacked resist film forming modules 21. Specifically, it is possible to prevent the height in the vertical direction of the whole apparatus from becoming extremely large when the resist film forming modules 21 are stacked at eight or more stages.

Further, in this embodiment, the electropneumatic regulator 251 is not integrated with the dispense pump 112 but is a separate body as explained above. In particular, the portion including the circuit board used for control of the pressure in the operating chamber in the electropneumatic regulator 251 is a separate body from the dispense pump 112. This makes it possible to prevent the resist solution in the dispense pump 112 from increasing in temperature under the influence of the temperature of the electropneumatic regulator 251 (specifically, the above circuit board) which gets high temperature during the execution of control. As a result, it is possible to prevent the occurrence of adverse effects due to the increase in temperature of the resist solution.

Further, in this embodiment, the one end of the return pipeline 160 constituting the circulation path provided with the filter 111 is branched from the supply pipeline 150 in the discharge control valve V21. Therefore, according to this embodiment, it is possible to circulate the resist solution also for a portion close to the discharge nozzle 21a on the supply pipeline 150. In other words, it is possible to reduce the resist solution which does not circulate in the circulation path but stays in the supply pipeline 150. Because the resist solution staying in the supply pipeline 150 may have foreign substances mixed therein, it is preferable to discard the resist solution, but if the resist solution staying in the supply pipeline 150 can be reduced as in this embodiment, it is possible to reduce the amount of discarded resist solution to thereby achieve chemical saving.

Further, in this embodiment, the flow rate of the resist solution flowing through the supply pipe 153 is measured by the flowmeter 240 which is arranged outside the supply pipe 153 and has no gas-liquid interface with the resist solution. Therefore, it is possible to prevent the cleanliness of the resist solution from lowering due to the measurement of the flow rate of the resist solution.

Further, as explained above, in this embodiment, the replenishment of the resist solution may be performed from the vertical upper side end of the storage chamber 112a of the dispense pump 112, and the resist solution may be pressure-fed from the vertical lower side end of the storage chamber 112a and supplied to the discharge nozzle 21a of the resist film forming module 21. Thus, even if air bubbles occur in the resist solution in the storage chamber 112a during the replenishment of the resist solution or the like, it is possible to prevent the air bubbles from flowing to the downstream side of the dispense pump 112.

Further, as explained above, during the circulation operation of the resist solution, the detection by the foreign substance detector 230 may be performed a plurality of times. In the case where the foreign substance detector 230 increases in detection sensitivity with an increase in the number of times of detection, if the detection is performed the number of times as explained above, the detection sensitivity can be improved.

Further, as explained above, during the circulation operation, the flow velocity of the resist solution may be made lower than that during the discharge operation. The foreign substance detector 230 may be affected in detection accuracy by the flow velocity of the resist solution, and a desired detection accuracy cannot be obtained in some cases at a high flow velocity. In this case, by decreasing the flow velocity of the resist solution during the circulation operation as above, the detection accuracy can be improved.

Further, as explained above, in the case where the foreign substance detector 230 is provided for each resist film forming module 21, the foreign substance detector 230 may also be arranged adjacent to the corresponding resist film forming module 21 in the width direction (Y-direction), in the carrier block D1. This makes it possible to prevent the flow rate of the resist solution at the arrangement position of the foreign substance detector 230 from varying among the resist film forming modules 21. As a result, it is possible to prevent the detection accuracy by the foreign substance detector 230 from varying among the resist film forming modules 21.

Furthermore, in this embodiment, the solution feeder 110 and the foreign substance detector 230 may be housed in a space partitioned from the space where the resist film forming module 21 is provided and adjacent to the space in the width direction (Y-direction). Accordingly, it is possible to perform maintenance of the dispense pump 112 of the solution feeder 110, the foreign substance detector 230, and so on without stopping the treatment by the resist film forming module 21. As a result, it is possible to keep the performance regarding the defects by the maintenance while suppressing a decrease in throughput.

Further, in this embodiment, the supply pipeline 150 has the downstream-side end connected to the corresponding resist film forming module 21 and the upstream-side end connected to the plurality of resist solution bottles 101. Further, the supply pipeline 150 has, for each resist solution bottle 101, the opening/closing valve V1a, V1b for switching between execution and stop of the replenishment of the resist solution from the resist solution bottle 101. On the supply pipeline 150, at the replenishment of the resist solution to the solution supply unit 100 from one of the resist solution bottles 101, only one of the opening/closing valves V1a, V1b which corresponds to the resist solution bottle 101 is brought into an open state and the other is brought into a closed state. Thus, the supply of the resist solution is not stopped during the replacement of the resist solution bottle 101 without the temporary storage such as the buffer tank for temporarily storing the resist solution which has been stored in the resist solution bottle 101 interposed in the supply pipeline 150, so that it is possible to continue the treatment.

<Another Example of the Solution Supply Unit>

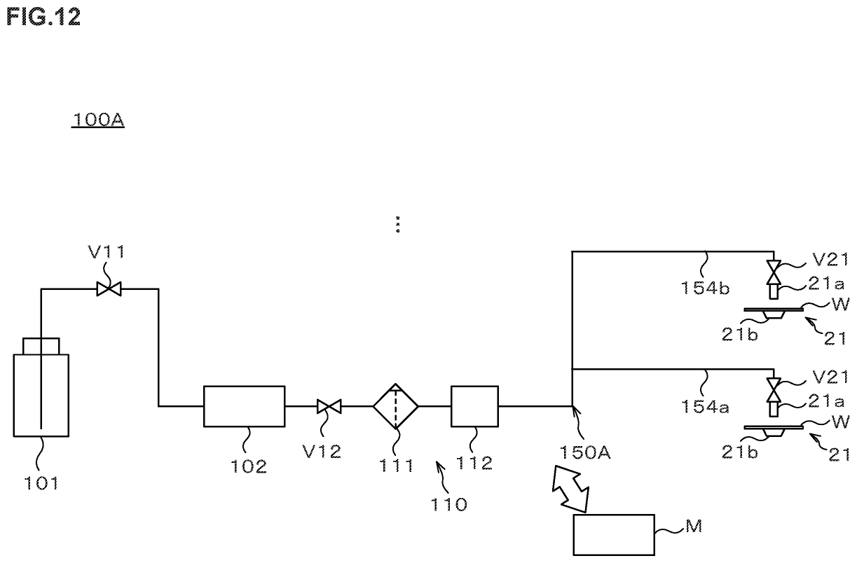

FIG. 12 is an explanatory view illustrating the outline of another example of the configuration of the solution supply unit.

A solution supply unit 100A in FIG. 12 has, similarly to the solution supply unit 100 in the above example, a supply pipeline 150A provided with the solution feeder 110, corresponding to the resist film forming module 21. However, unlike the solution supply unit 100, the solution supply unit 100A does not have, for each resist film forming module 21, the supply pipeline 150A provided with the solution feeder 110. The solution supply unit 100A has, for two resist film forming modules 21, one supply pipeline 150A provided with the solution feeder 110. The downstream-side end of the supply pipeline 150A is connected to the corresponding resist film forming modules 21. Specifically, the downstream-side end portion of the supply pipeline 150A is branched into branch supply pipelines 154a, 154b, and the downstream-side end of the branch supply pipeline 154a is connected to the discharge nozzle 21a of one of the two corresponding resist film forming modules 21 and the downstream-side end of the branch supply pipeline 154b is connected to the discharge nozzle 21a of the other of the two corresponding resist film forming modules 21.

The supply pipeline 150A is provided with one solution feeder 110. In other words, the solution supply unit 100A has one solution feeder 110 for the two resist film forming modules 21. The solution feeder 110 is provided on the upstream side from the branch portion of the supply pipeline 150A into the branch supply pipelines 154a, 154b.

Note that though not illustrated, a regulator which controls the operation of the discharge control valve V21 and a regulator which controls the operation of the dispense pump 112 are provided in the solution supply unit 100A as in the solution supply unit 100. Further, also in the solution supply unit 100A, the regulators are separate bodies from the discharge control valve V21 and the dispense pump 112. In particular, portions including a circuit board used for control in the regulators are arranged at positions away from the discharge control valve V21 and the dispense pump 112.

Further, the number of the resist solution bottles 101 connected to the upstream-side end of the supply pipeline 150A is one in the solution supply unit 100A unlike the solution supply unit 100. However, the upstream side of the supply pipeline 150A may be branched as in the solution supply unit 100 in FIG. 4 and the resist solution bottle 101 may be connected to the upstream-side end of each of the branched ones.

Further, the solution supply unit 100A does not have the return pipeline 160 unlike the solution supply unit 100.

However, the solution supply unit 100A may have the return pipeline 160. In this case, the return pipeline 160 is provided for each branch supply pipeline 154, namely, each discharge nozzle 21a. The one end of each of the return pipelines 160 is branched from the corresponding branch supply pipeline 154. The other ends of the return pipelines 160 join together and are connected to the downstream side of the first opening/closing valve V11 and the upstream side of the dispense pump 112 and the filter 111 on the corresponding supply pipeline 150A. Accordingly, each of the return pipelines 160 constitutes a circulation path of the treatment solution together with the corresponding branch supply pipeline 154 and a portion where the dispense pump 112 and the filter 111 are interposed in the corresponding supply pipeline 150A.

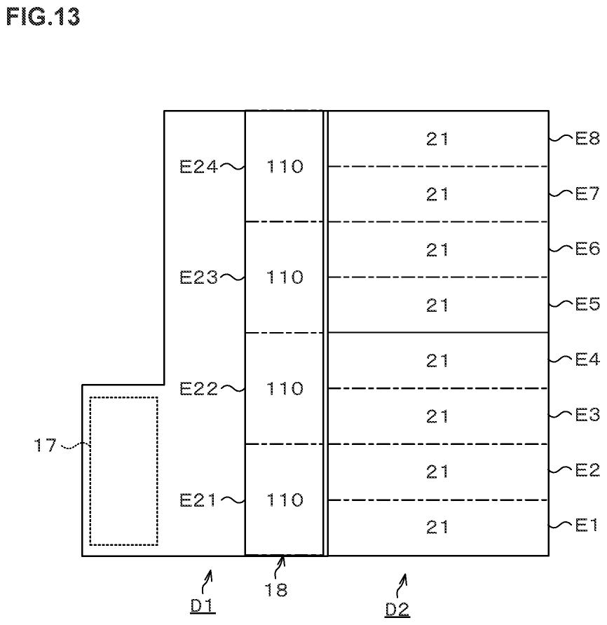

FIG. 13 is a view for explaining the position of the solution feeder 110 in the case of using the solution supply unit 100A.

In the case of using the solution supply unit 100A, the housing region 18 is divided along the vertical direction into a plurality of layers, and the solution feeder 110 is housed in each of the layers as illustrated in FIG. 13 as in the case of using the solution supply unit 100 in FIG. 4. However, in the case of using the solution supply unit 100A, the housing region 18 is partitioned into tiers of the number that is half (four in the example of the drawing) of the number of resist film forming modules 21 stacked in the vertical direction in the first stack treatment block D2 unlike the case of using the solution supply unit 100 in FIG. 4. In the following, the four tiers are called tiers E21 to E24 in order from the lower side.

The tier E21 overlaps with both the tier E1 and the tier E2 in height position, and houses the solution feeder 110 interposed in the supply pipeline 150A corresponding to the resist film forming modules 21 provided at the tiers E1 and E2.

Similarly, the tier E22 overlaps with both the tier E3 and the tier E4 in height position, and houses the solution feeder 110 interposed in the supply pipeline 150A corresponding to the resist film forming modules 21 provided at the tiers E3 and E4.

This also applies to the tiers E23, E24.

In this manner, also in the case of using the solution supply unit 100A, each solution feeder 110 is arranged adjacent to the corresponding resist film forming modules 21 in the width direction (Y-direction) being the horizontal direction, in the carrier block D1.

Also in this example, as compared with the above comparative form, the distance from the filter 111 to the discharge nozzle 21a can be shortened for each of the plurality of resist film forming modules 21 included in the coating and developing apparatus 1. Accordingly, it is possible to suppress the occurrence of defects when treating the wafer W using the supplied resist solution for each of the resist film forming modules 21.

Further, in this example, the level difference between the dispense pump 112 and the discharge nozzle 21a, namely, the head difference can be made smaller among the resist film forming modules 21 as compared with the case where the dispense pump 112 is common among all of the resist film forming modules 21 included in the coating and developing apparatus 1. Accordingly, it is possible to easily obtain a desired discharge performance for each of the resist film forming modules 21.

Further, in this example, one solution feeder 110 is provided for two resist film forming modules 21, namely, the two resist film forming modules 21 share one dispense pump 112. Therefore, it is possible to reduce the cost as compared with the case where the dispense pump 112 is provided for each resist film forming module 21.

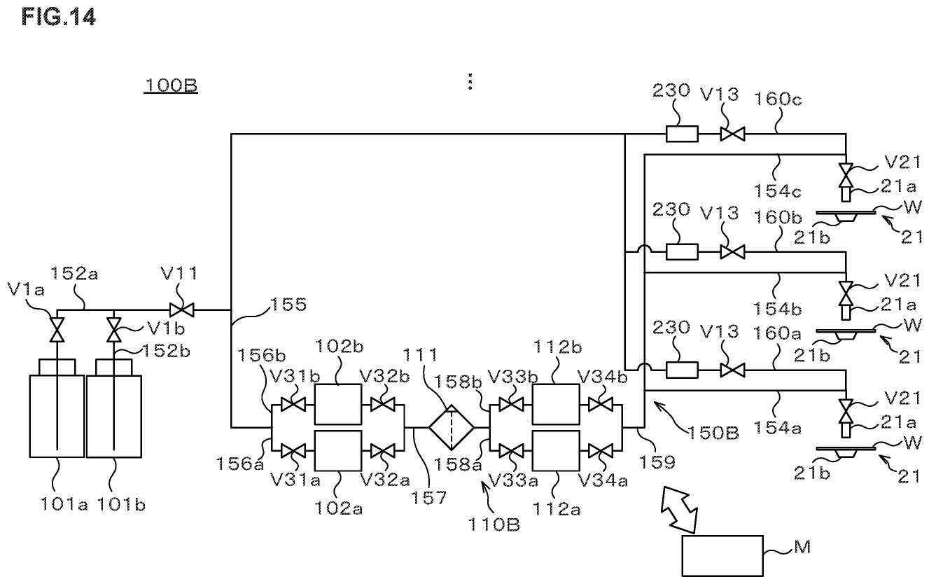

FIG. 14 is an explanatory view illustrating the outline of still another example of the configuration of the solution supply unit.

A solution supply unit 100B in FIG. 14 has, similarly to the solution supply unit 100 in FIG. 4, a supply pipeline 150B provided with a solution feeder 110B, corresponding to the resist film forming module 21. However, unlike the solution supply unit 100, the solution supply unit 100B does not have, for each resist film forming module 21, the supply pipeline 150B provided with the solution feeder 110B. The solution supply unit 100B has, for three resist film forming modules 21, one supply pipeline 150B provided with one solution feeder 110B, and the supply pipeline 150B has two dispense pumps 112.

The supply pipeline 150B has a first supply pipeline 155, an assist pump branch pipeline 156, a second supply pipeline 157, a dispense pump branch pipeline 158, and a third supply pipeline 159.

The first supply pipeline 155 is branched into branch supply pipelines 152a, 152b at the upstream side, and provided with the first opening/closing valve V11. To the downstream-side end of the first supply pipeline 155, assist pump branch pipelines 156a, 156b are connected in parallel.

An assist pump 102a is interposed in the assist pump branch pipeline 156a, and an opening/closing valve V31a and an opening/closing valve V32a are interposed on the upstream side and the downstream side of the assist pump 102a, respectively.

An assist pump 102b is interposed in the assist pump branch pipeline 156b, and an opening/closing valve V31b and an opening/closing valve V32b are interposed on the upstream side and the downstream side of the assist pump 102b, respectively.

The downstream-side ends of the assist pump branch pipelines 156a, 151b are connected to the upstream-side end of the second supply pipeline 157.

The second supply pipeline 157 is provided with the filter 111 constituting the solution feeder 110B. To the downstream-side end of the second supply pipeline 157, dispense pump branch pipelines 158a, 158b are connected in parallel.

A dispense pump 112a constituting the solution feeder 110B is interposed in the dispense pump branch pipeline 158a, and an opening/closing valve V33a and an opening/closing valve V34a are provided on the upstream side and the downstream side of the dispense pump 112a, respectively.

A dispense pump 112b constituting the solution feeder 110B is interposed in the dispense pump branch pipeline 158b, and an opening/closing valve V33b and an opening/closing valve V34b are provided on the upstream side and the downstream side of the dispense pump 112b, respectively.

The downstream-side ends of the dispense pump branch pipelines 158a, 158b are connected to the upper side end of the third supply pipeline 159.

The downstream-side end portion of the third supply pipeline 159 is branched into branch supply pipelines 154a, 154b, 154c.

The downstream-side end of the branch supply pipeline 154a is connected to the discharge nozzle 21a included in a first resist film forming module 21 among the three resist film forming modules 21 corresponding to the supply pipeline 150B.

The downstream-side end of the branch supply pipeline 154b is connected to the discharge nozzle 21a included in a second resist film forming module 21 among the three resist film forming modules 21 corresponding to the supply pipeline 150B.

The downstream-side end of the branch supply pipeline 154c is connected to the discharge nozzle 21a included in a third resist film forming module 21 among the three resist film forming modules 21 corresponding to the supply pipeline 150B.

Further, the solution supply unit 100B has the return pipeline 160 for each branch supply pipeline 154, namely, for each discharge nozzle 21a. A return pipeline 160a is provided for the branch supply pipelines 154a, a return pipeline 160b is provided for the branch supply pipelines 154b, and a return pipeline 160c is provided for the branch supply pipelines 154c.

One end of the return pipeline 160 is branched from the corresponding branch supply pipeline 154. The other ends of the return pipelines 160a to 160c join together and are connected to the downstream side of the first opening/closing valve V11 and the upstream side of the dispense pump 112 and the filter 111 on the supply pipeline 150B. Specifically, the other ends of the return pipelines 160a to 160c are connected to the downstream side of the first opening/closing valve V11 on the first supply pipeline 155.

Accordingly, each of the return pipelines 160 constitutes a circulation path of the treatment solution together with the corresponding branch supply pipeline 154 and a portion where the dispense pump 112 and the filter 111 are interposed in the corresponding supply pipeline 150B.

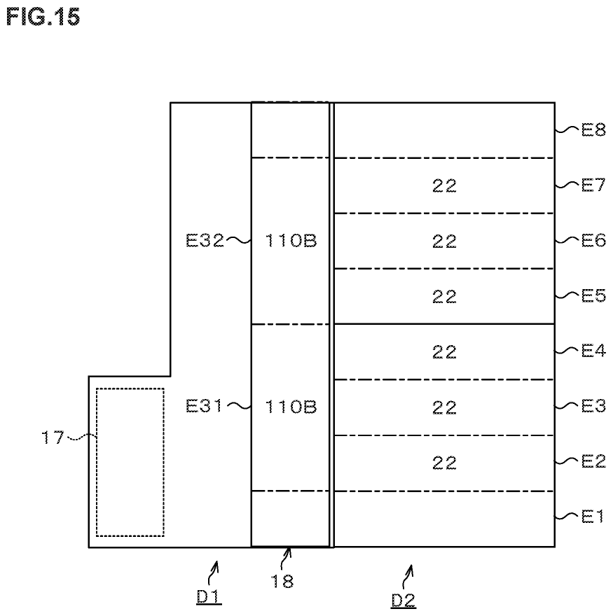

FIG. 15 is a view for explaining a position of the solution feeder 110B in the case of using the solution supply unit 100B.

In the case of using the solution supply unit 100B, the housing region 18 is divided along the vertical direction into a plurality of layers and the solution feeder 110B is housed at each of the layers as illustrated in FIG. 15 as in the case of using the solution supply unit 100 in FIG. 4. However, in the case of using the solution supply unit 100B, the housing region 18 is configured to have a tier that is twice or more in height than the tier where the resist film forming module 21 is provided in the first stack treatment block D2 unlike the case of using the solution supply unit 100 in FIG. 4. The housing region 18 includes tiers E31, E32 in this order from the bottom.

The tier E31 overlaps with all of the tiers E2 to E4 in height position, and houses the solution feeder 110B interposed in the supply pipeline 150B corresponding to the resist film forming modules 21 provided at the tiers E2 to E4.

Similarly, the tier E32 overlaps with all of the tiers E5 to E7 in height position, and houses the solution feeder 110B interposed in the supply pipeline 150B corresponding to the resist film forming modules 21 provided at the tiers E5 to E7.

In this manner, also in the case of using the solution supply unit 100B, each of the solution feeders 110B is arranged adjacent to the corresponding resist film forming modules 21 in the width direction (Y-direction) being the horizontal direction, in the carrier block D1.

Also in this example, as compared with the comparative form, the distance from the filter 111 to the discharge nozzle 21a can be shortened for each of the plurality of resist film forming modules 21 included in the coating and developing apparatus 1. Accordingly, it is possible to suppress the occurrence of defects when treating the wafer W using the supplied resist solution for each of the resist film forming modules 21.

Further, also in this example, the level difference between the dispense pump 112 and the discharge nozzle 21a, namely, the head difference can be made smaller among the resist film forming modules 21 as compared with the case where the dispense pump 112 is common among all of the resist film forming modules 21 included in the coating and developing apparatus 1. Therefore, according to this embodiment, it is possible to easily obtain a desired discharge performance for each of the resist film forming modules 21.

Further, in this example, the three resist film forming modules 21 share the two dispense pumps 112. Therefore, it is possible to reduce the cost as compared with the case where the dispense pump 112 is provided for each resist film forming module 21.

Note that in the case of the solution supply unit 100B in this example, it is possible to perform the replenishment of the treatment solution to one dispense pump 112 while using the other dispense pump 112 for the discharge of the treatment solution from the discharge nozzle 21a. Further, it is possible to perform the replenishment of the treatment solution to one assist pump 102 while using the other assist pump 102 for the replenishment of the treatment solution to the dispense pump 112.

<Other Modification Examples>

The treatment solution supplied by the solution supply apparatus is a resist solution in the above, but may be a coating solution being a treatment solution for forming a coating film (for example, an anti-reflection film) other than the resist solution. Further, it may be a treatment solution other than the coating solution.

Besides, the solution feeder 110 is provided in the carrier block D1 in the above example, but may be provided in the interface block D4 depending on the arrangement position of the solution treatment module at the feeding destination of the treatment solution. Specifically, in the case where the solution treatment module at the feeding destination of the treatment solution is provided in the second stack treatment block D3, the solution feeder 110 may be provided in the interface block D4.

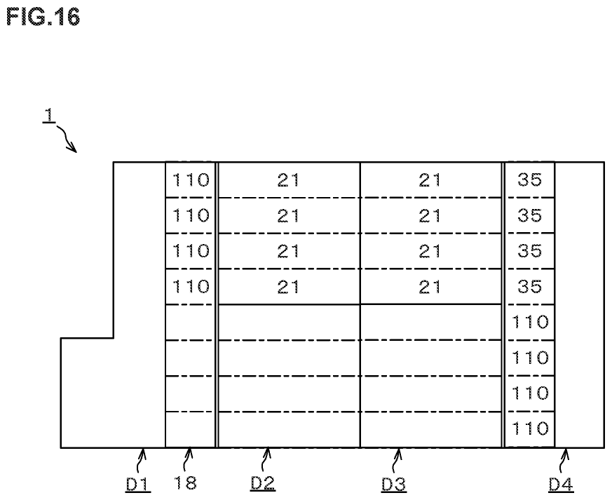

Note that for some of the solution treatment modules being feeding targets of the treatment solution from the solution supply unit 100 in the coating and developing apparatus 1, the corresponding solution feeders 110 do not need to be arranged adjacent in the horizontal direction. For example, as illustrated in FIG. 16, the solution feeders 110 for the resist film forming modules 21 provided in the second stack treatment block D3 are provided at positions (specifically, lower positions) in the interface block D4, not overlapping with the resist film forming modules 21 in the height direction, in the case where other modules such as the rear surface cleaning modules 35 are provided at portions in the interface block D4 adjacent to the resist film forming modules 21 in the horizontal direction, and therefore the solution feeders 110 cannot be provided at the adjacent portions.

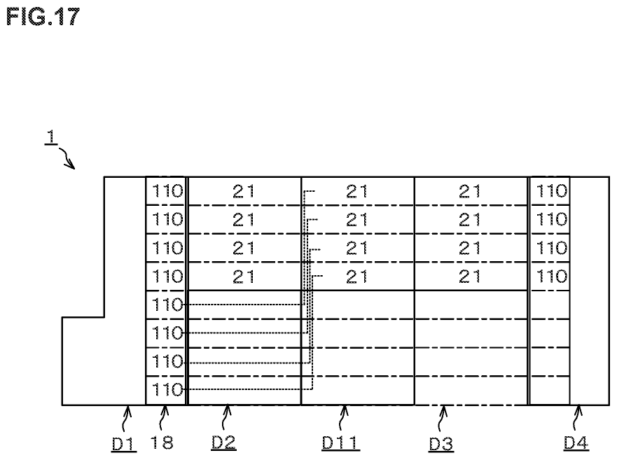

Besides, as illustrated in FIG. 17, the coating and developing apparatus 1 may further have a stack treatment block D11 (hereinafter, referred to as an “intermediate stack treatment block D11”) between the first stack treatment block D2 and the second stack treatment block D3. In this case, for the resist film forming modules 21 provided in the intermediate stack treatment block D11, the corresponding solution feeders 110 do not need to be provided adjacent in the horizontal direction. For example, in this case, for the resist film forming modules 21 provided in the intermediate stack treatment block D11, the corresponding solution feeders 110 may be provided at positions (specifically, lower positions) in the carrier block D1, not overlapping with the resist film forming modules 21 in the height direction. Instead of this, for the resist film forming modules 21 provided in the intermediate stack treatment block D11, the corresponding solution feeders 110 may be provided at positions in the interface block D4, not overlapping with the resist film forming modules 21 in the height direction.

In the case where for some of the solution treatment modules being destination targets of the treatment solution from the solution supply unit 100 in the coating and developing apparatus 1, the corresponding solution treatment modules are stacked and the corresponding solution feeders 110 are not arranged adjacent to them in the horizontal direction as in the above, the head difference between the solution treatment module and the corresponding solution feeder may be made equal among the stacked solution treatment modules. Specifically, for example, for the module at an n+4-th (n is a natural number) layer among the resist film forming modules 21 provided in the intermediate stack treatment block D11, the corresponding solution feeder 110 may be provided at an n-th layer in the carrier block D1 as indicated by the dotted line in FIG. 17.

In the return pipeline 160, an inside diameter of a pipe wall of a detection target portion by the foreign substance detector 230 may be smaller than that of the other portion. This makes it possible to collect the foreign substances to the detection target portion to thereby improve the detection accuracy of the foreign substances. Note that because the return pipeline 160 less affects the discharge performance of the treatment solution from the discharge nozzle 21a, it is easy to change the inside diameter of the pipe wall.

The embodiments disclosed herein are examples in all respects and should not be considered to be restrictive. Various omissions, substitutions and changes may be made in the embodiment without departing from the scope and spirit of the attached claims. For example, configuration requirements of the above embodiments can be arbitrarily combined. The operations and effects about the configuration requirements relating to the combination can be obtained as a matter of course from the arbitrary combination, and those skilled in the art can obtain clear other operations and effects from the description herein.

The effects described herein are merely explanatory or illustrative in all respects and not restrictive. The technique relating to this disclosure can offer other clear effects to those skilled in the art from the description herein in addition to or in place of the above effects.

Note that the following configuration examples also belong to the technical scope of this disclosure.

(1) A substrate treatment apparatus including:
a plurality of solution treatment modules stacked at multiple stages, each configured to perform a treatment using a treatment solution on a substrate; and
a solution supply unit configured to supply the treatment solution to the plurality of solution treatment modules, wherein:
the solution supply unit includes supply pipelines provided with a solution feeder, corresponding to the solution treatment modules; and
the solution feeder includes a pump configured to pressure-feed the treatment solution to the corresponding solution treatment module and a filter configured to filtrate the treatment solution, and is arranged adjacent to the corresponding solution treatment module in a horizontal direction.
   (2) The substrate treatment apparatus according to the (1), wherein
the solution supply unit includes the supply pipeline for each of the solution treatment modules.
   (3) The substrate treatment apparatus according to the (1) or (2), wherein:
the solution treatment module includes a discharge nozzle configured to discharge the treatment solution supplied to the solution treatment module; and
the supply pipeline has one end connected to the discharge nozzle of the corresponding solution treatment module, and is provided with a discharge control valve configured to control discharge of the treatment solution from the discharge nozzle, on a downstream side of the solution feeder.
   (4) The substrate treatment apparatus according to the (3), wherein:
the solution supply unit further includes a regulator configured to control an operation of the discharge control valve; and
the regulator is configured as a separate body from the discharge control valve.
   (5) The substrate treatment apparatus according to any one of the (1) to (4), wherein:
the solution supply unit further includes a regulator configured to control an operation of the pump; and
the regulator is configured as a separate body from the pump.
   (6) The substrate treatment apparatus according to any one of the (1) to (5), wherein
the supply pipeline has one end connected to the corresponding solution treatment module, has another end connected to a plurality of storage sources each configured to store the treatment solution, and is provided with a switching valve configured to switch between execution and stop of replenishment of the treatment solution from the storage source, for each storage source; and
at the replenishment from the storage source to the solution supply unit, only the switching valve corresponding to the storage source is brought into an open state and the other switching valve is brought into a closed state.
   (7) The substrate treatment apparatus according to any one of the (1), (2), (4) to (6), wherein:
the solution supply unit further includes a return pipeline having one end branched from a downstream side of the pump and the filter on the supply pipeline, and another end connected to an upstream side of the pump and the filter on the supply pipeline; and
the return pipeline constitutes a circulation path of the treatment solution together with a portion, of the supply pipeline, provided with the pump and the filter.
   (8) The substrate treatment apparatus according to (3), wherein:
the solution supply unit further includes a return pipeline having one end branched from a downstream side of the pump and the filter on the supply pipeline, and another end connected to an upstream side of the pump and the filter on the supply pipeline;
the return pipeline constitutes a circulation path of the treatment solution together with a portion, of the supply pipeline, provided with the pump and the filter; and
the one end of the return pipeline is branched from the supply pipeline in the discharge control valve.
   (9) The substrate treatment apparatus according to any one of the (1) to (8), wherein
the pump is a phragm pump having a storage chamber, and a vertical upper side end of the storage chamber is a primary side of the pump and a vertical lower side end of the storage chamber is a secondary side of the pump.
   (10) The substrate treatment apparatus according to any one of the (1) to (9), wherein:
the supply pipeline includes a supply pipe through which the treatment solution flows; and
the solution supply unit further includes a flowmeter arranged outside the supply pipe and configured to measure a flow rate of the treatment solution flowing through the supply pipeline.
   (11) The substrate treatment apparatus according to any one of the (6) to (8), wherein
the return pipeline is provided with a foreign substance detector configured to detect a foreign substance in the treatment solution flowing through the return pipeline.
   (12) A treatment solution supply method using a substrate treatment apparatus,
the substrate treatment apparatus including:
a plurality of solution treatment modules stacked at multiple stages, each configured to perform a treatment using a treatment solution on a substrate; and
a solution supply unit configured to supply the treatment solution to the plurality of solution treatment modules,
the solution supply unit including supply pipelines provided with a feeder, corresponding to the solution treatment modules; and
the solution feeder including a pump configured to pressure-feed the treatment solution to the corresponding solution treatment module and a filter configured to filtrate the treatment solution,
the treatment solution supply method including supplying the treatment solution to the solution treatment module, wherein
the supplying the treatment solution supplies the treatment solution from the solution feeder corresponding to the solution treatment module at a supply destination and arranged adjacent to the solution treatment module in a horizontal direction.
   (13) The treatment solution supply method according to the (12), wherein
the solution supply unit includes the supply pipeline for each of the solution treatment modules.
   (14) The treatment solution supply method according to the (12) or (13), wherein:
the solution treatment module includes a discharge nozzle configured to discharge the treatment solution supplied to the solution treatment module; and
the supply pipeline has one end connected to the discharge nozzle of the corresponding solution treatment module, and is provided with a discharge control valve configured to control discharge of the treatment solution from the discharge nozzle, on a downstream side of the solution feeder.
   (15) The treatment solution supply method according to (15), further including
controlling an operation of the discharge control valve by a regulator configured as a separate body from the discharge control valve.
   (16) The treatment solution supply method according to any one of the (12) to (15), further including
controlling an operation of the pump by a regulator configured as a separate body from the pump.
   (17) The treatment solution supply method according to the (12), (13), (15), or (16), further including
returning the treatment solution passed through the pump and the filter in the supply pipeline to an upstream side of the pump and the filter on the supply pipeline, and circulating the treatment solution.
   (18) The treatment solution supply method according to the (14), further including
returning the treatment solution passed through the pump and the filter in the supply pipeline to an upstream side of the pump and the filter on the supply pipeline, and circulating the treatment solution, wherein
the circulating returns the treatment solution passed through the pump and the filter in the supply pipeline from an inside of the discharge control valve to an upstream side of the pump and the filter on the supply pipeline, and circulates the treatment solution.
   (19) The treatment solution supply method according to any one of the (12) to (18), further including:
replenishing a storage chamber of a phragm pump as the pump with the treatment solution from a vertical upper side end of the storage chamber; and
pressure-feeding the treatment solution in the storage chamber from a vertical lower side end of the storage chamber.
   (20) The treatment solution supply method according to the (17) or (18), further including:
detecting a foreign substance in the treatment solution to be returned to the upstream side of the pump and the filter on the supply pipeline.

According to this disclosure, the occurrence of defects is suppressed in each solution treatment module in a substrate treatment apparatus in which a plurality of solution treatment modules are stacked at multiple stages.

What is claimed is:

1. A substrate treatment apparatus comprising:
a plurality of solution treatment modules stacked at multiple stages, each configured to perform a treatment using a treatment solution on a substrate; and
a solution supply unit configured to supply the treatment solution to the plurality of solution treatment modules, wherein:
the solution supply unit comprises supply pipelines provided with a solution feeder, corresponding to the solution treatment modules; and
the solution feeder comprises a pump configured to pressure-feed the treatment solution to the corresponding solution treatment module and a filter configured to filtrate the treatment solution, and is arranged adjacent to the corresponding solution treatment module in a horizontal direction.

2. The substrate treatment apparatus according to claim 1, wherein
the solution supply unit comprises the supply pipeline for each of the solution treatment modules.

3. The substrate treatment apparatus according to claim 1, wherein:
the solution treatment module comprises a discharge nozzle configured to discharge the treatment solution supplied to the solution treatment module; and
the supply pipeline has one end connected to the discharge nozzle of the corresponding solution treatment module, and is provided with a discharge control valve configured to control discharge of the treatment solution from the discharge nozzle, on a downstream side of the solution feeder.

4. The substrate treatment apparatus according to claim 3, wherein:
the solution supply unit further comprises a regulator configured to control an operation of the discharge control valve; and
the regulator is configured as a separate body from the discharge control valve.

5. The substrate treatment apparatus according to claim 1, wherein:
the solution supply unit further comprises a regulator configured to control an operation of the pump; and
the regulator is configured as a separate body from the pump.

6. The substrate treatment apparatus according to claim 1, wherein
the supply pipeline has one end connected to the corresponding solution treatment module, has another end connected to a plurality of storage sources each configured to store the treatment solution, and is provided with a switching valve configured to switch between execution and stop of replenishment of the treatment solution from the storage source, for each storage source; and
at the replenishment from the storage source to the solution supply unit, only the switching valve corresponding to the storage source is brought into an open state and the other switching valve is brought into a closed state.

7. The substrate treatment apparatus according to claim 1, wherein:
the solution supply unit further comprises a return pipeline having one end branched from a downstream side of the pump and the filter on the supply pipeline, and another end connected to an upstream side of the pump and the filter on the supply pipeline; and
the return pipeline constitutes a circulation path of the treatment solution together with a portion, of the supply pipeline, provided with the pump and the filter.

8. The substrate treatment apparatus according to claim 2, wherein:
the solution supply unit further comprises a return pipeline having one end branched from a downstream side of the pump and the filter on the supply pipeline, and another end connected to an upstream side of the pump and the filter on the supply pipeline;
the return pipeline constitutes a circulation path of the treatment solution together with a portion, of the supply pipeline, provided with the pump and the filter; and
the one end of the return pipeline is branched from the supply pipeline in the discharge control valve.

9. The substrate treatment apparatus according to claim 1, wherein
the pump is a phragm pump having a storage chamber, and a vertical upper side end of the storage chamber is a primary side of the pump and a vertical lower side end of the storage chamber is a secondary side of the pump.

10. The substrate treatment apparatus according to claim 1, wherein:
the supply pipeline comprises a supply pipe through which the treatment solution flows; and
the solution supply unit further comprises a flowmeter arranged outside the supply pipe and configured to measure a flow rate of the treatment solution flowing through the supply pipeline.

11. The substrate treatment apparatus according to claim 7, wherein
the return pipeline is provided with a foreign substance detector configured to detect a foreign substance in the treatment solution flowing through the return pipeline.

12. A treatment solution supply method using a substrate treatment apparatus,
the substrate treatment apparatus comprising:
a plurality of solution treatment modules stacked at multiple stages, each configured to perform a treatment using a treatment solution on a substrate; and
a solution supply unit configured to supply the treatment solution to the plurality of solution treatment modules,
the solution supply unit comprising supply pipelines provided with a solution feeder, corresponding to the solution treatment modules; and
the solution feeder comprising a pump configured to pressure-feed the treatment solution to the corresponding solution treatment module and a filter configured to filtrate the treatment solution,
the treatment solution supply method comprising supplying the treatment solution to the solution treatment module, wherein
the supplying the treatment solution supplies the treatment solution from the solution feeder corresponding to the solution treatment module at a supply destination and arranged adjacent to the solution treatment module in a horizontal direction.

13. The treatment solution supply method according to claim 12, wherein
the solution supply unit comprises the supply pipeline for each of the solution treatment modules.

14. The treatment solution supply method according to claim 12, wherein:
the solution treatment module comprises a discharge nozzle configured to discharge the treatment solution supplied to the solution treatment module; and
the supply pipeline has one end connected to the discharge nozzle of the corresponding solution treatment module, and is provided with a discharge control valve configured to control discharge of the treatment solution from the discharge nozzle, on a downstream side of the solution feeder.

15. The treatment solution supply method according to claim 14, further comprising
controlling an operation of the discharge control valve by a regulator configured as a separate body from the discharge control valve.

16. The treatment solution supply method according to claim 12, further comprising
controlling an operation of the pump by a regulator configured as a separate body from the pump.

17. The treatment solution supply method according to claim 12, further comprising
returning the treatment solution passed through the pump and the filter in the supply pipeline to an upstream side of the pump and the filter on the supply pipeline, and circulating the treatment solution.

18. The treatment solution supply method according to claim 14, further comprising
returning the treatment solution passed through the pump and the filter in the supply pipeline to an upstream side of the pump and the filter on the supply pipeline, and circulating the treatment solution, wherein
the circulating returns the treatment solution passed through the pump and the filter in the supply pipeline from an inside of the discharge control valve to an upstream side of the pump and the filter on the supply pipeline, and circulates the treatment solution.

19. The treatment solution supply method according to claim 12, further comprising:
replenishing a storage chamber of a phragm pump as the pump with the treatment solution from a vertical upper side end of the storage chamber; and
pressure-feeding the treatment solution in the storage chamber from a vertical lower side end of the storage chamber.

20. The treatment solution supply method according to claim 17, further comprising:
detecting a foreign substance in the treatment solution to be returned to the upstream side of the pump and the filter on the supply pipeline.
